(19) United States
(12) Patent Application Publication
(10) Pub. No.: US 2026/0020367 A1
(43) Pub. Date: Jan. 15, 2026

(54) IMAGE SENSOR DEVICE AND METHODS OF FORMATION

(71) Applicant: Taiwan Semiconductor Manufacturing Company, Ltd., Hsinchu (TW)

(72) Inventors: Eugene I-Chun CHEN, Zhubei City (TW); Chia-Shiung TSAI, Hsinchu City (TW); Kuan-Liang LIU, Tainan (TW)

(21) Appl. No.: 18/767,112

(22) Filed: Jul. 9, 2024

(51) Int. Cl. H01L 27/146; H04N 25/79

(52) U.S. Cl. CPC H10F 39/809; H04N 25/79; H10F 39/018

(57) ABSTRACT

An image sensor device may be formed by forming a stacked arrangement of semiconductor dies without the use of a high-temperature operations such as annealing when processing a semiconductor wafer that contains a semiconductor layer in which a sensor circuitry die of the image sensor device is to be formed. Instead, the semiconductor wafer includes one or more etch stop layers that enable a combination of low-temperature processes such as etching and planarization to be performed to thin down semiconductor wafer. The use of low-temperature processes instead of high-temperature processes to thin down the semiconductor wafer reduces the exposure of the photodiode(s) and other layers and/or structures of the sensor wafer to high temperatures that might otherwise damage these photodiode(s) and other layers and/or structures.

### BACKGROUND

A device-over-photodetector (DoP) image sensor device is a type of three-dimensional semiconductor device that includes a plurality of stacked or vertically arranged semiconductor dies that are bonded together. The semiconductor dies may each be formed on separate semiconductor wafers. One of the semiconductor wafers (e.g., a sensor wafer) includes the photodiode(s) and associated transfer gates of the DoP image sensor device. Another one of the semiconductor wafers (e.g., a sensor circuitry wafer) may include sensor circuitry, such as the source-follower gates, reset gates, and/or the row select gates associated with the photodiodes. A further one of the semiconductor wafers (e.g., a logic wafer) may include logic circuitry (e.g., transistors and other integrated circuit devices) configured to process signals generated by the photodiode(s).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1C are diagrams of an example image sensor device described herein.

FIGS. 2A-21 are diagrams of an example of forming sensor layers of image sensor devices formed on a sensor wafer.

FIGS. 3A-3P are diagrams of an example of forming sensor circuitry layers of image sensor devices formed on a sensor wafer.

FIGS. 4A-4C are diagrams of an example of bonding integrated circuit layers to image sensor devices formed on a sensor wafer.

FIGS. 5A-5C are diagrams of an example of forming sensor circuitry layers of image sensor devices formed on a sensor wafer.

FIG. 6 is a diagram of an example of elemental concentration as a function of depth in a semiconductor layer described herein.

FIG. 7 is a flowchart of an example process associated with forming an image sensor device described herein.

FIG. 8 is a flowchart of an example process associated with forming an image sensor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, the process operations that are performed to form a stacked arrangement of semiconductor dies of a device-over-photodetector (DoP) image sensor device may cause damage to one or more of the semiconductor wafers on which the semiconductor dies are formed. For example, high-temperature processes such as a high-temperature annealing operation may be performed after bonding a semiconductor wafer to a sensor wafer on which a sensor die of the image sensor device is formed. The semiconductor wafer contains a semiconductor layer in which the sensor circuitry of a sensor circuitry die of the DoP image sensor device is to be formed. The high-temperature annealing operation may damage the photodiode(s) in the sensor die. In particular, the high-temperature processes may introduce defects in the photodiode(s), resulting in increased dark current for the photodiode(s). Increased dark current may cause thermally-induced noise and/or reduced low-light performance for the photodiode(s). Additionally and/or alternatively, the high-temperature processes may alter the properties of the semiconductor material of the photodiode(s), leading to decreased quantum efficiency (QE) for the photodiode(s). Other parts of one or more of the semiconductor wafers, such as silicide contacts and device doping profiles, may also be damaged or degraded because of the high-temperature processes.

In some implementations described herein, an image sensor device (e.g., a DoP image sensor device) is formed by forming a stacked arrangement of semiconductor dies without the use of a high-temperature operations such as annealing when processing the semiconductor wafer that contains the semiconductor layer in which the sensor circuitry die of the image sensor device is to be formed. Instead, the semiconductor wafer includes one or more etch stop layers that enable a combination of low-temperature processes such as etching and planarization to be performed to thin down semiconductor wafer. The use of low-temperature processes instead of high-temperature processes to thin down the semiconductor wafer reduces the exposure of the photodiode(s) and other layers and/or structures of the sensor wafer (e.g., silicide contacts and/or doped regions) to high temperatures that might otherwise damage these photodiode(s) and other layers and/or structures. Thus, the techniques described herein may enable a low dark current to be achieved for the photodiode(s) and/or may enable a high QE to be achieved for the photodiodes, among other examples.

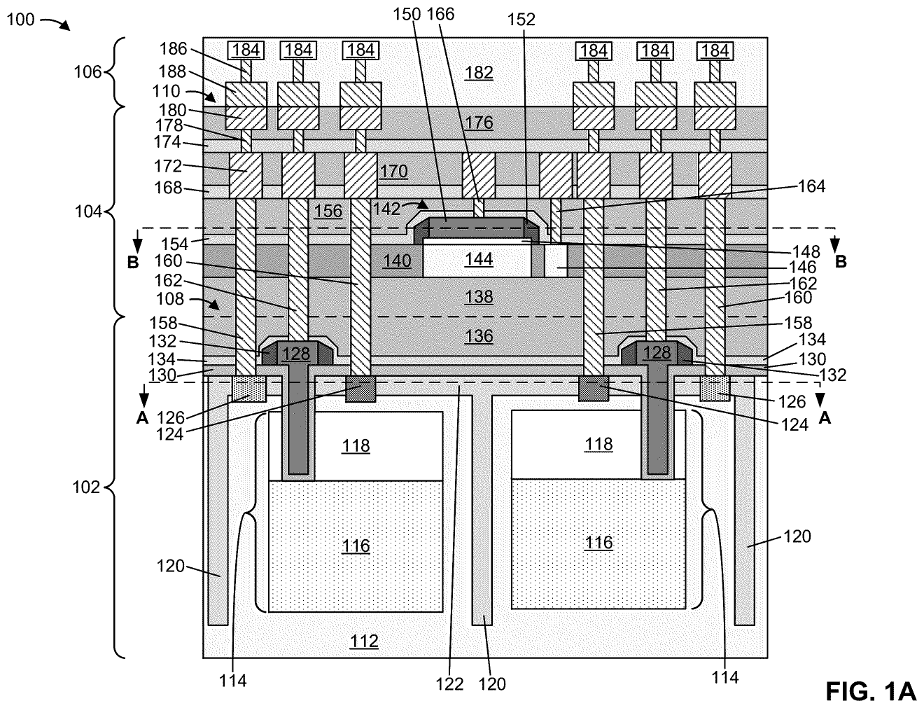

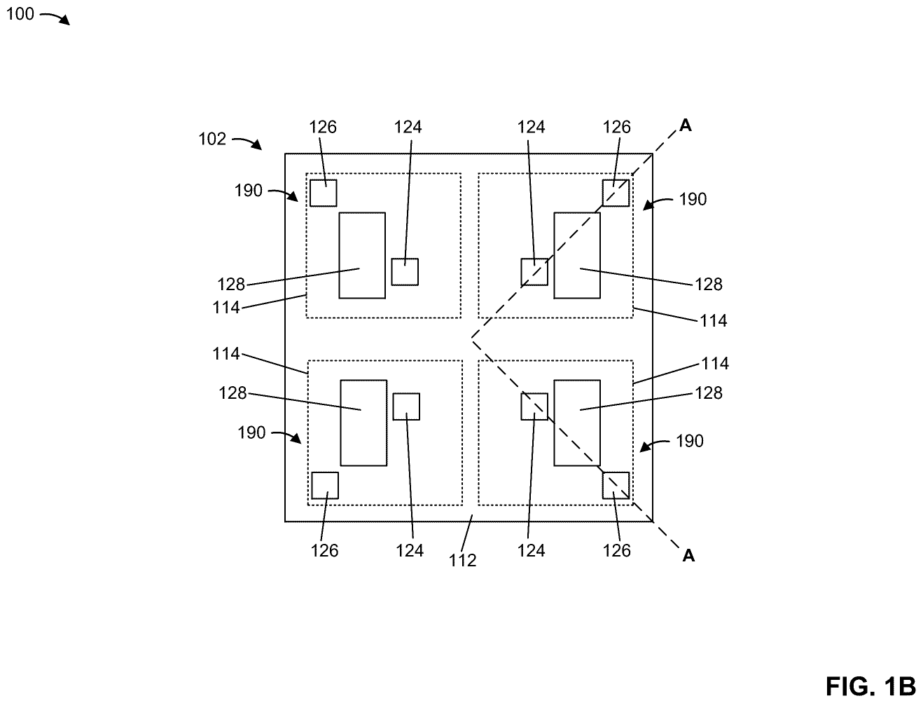

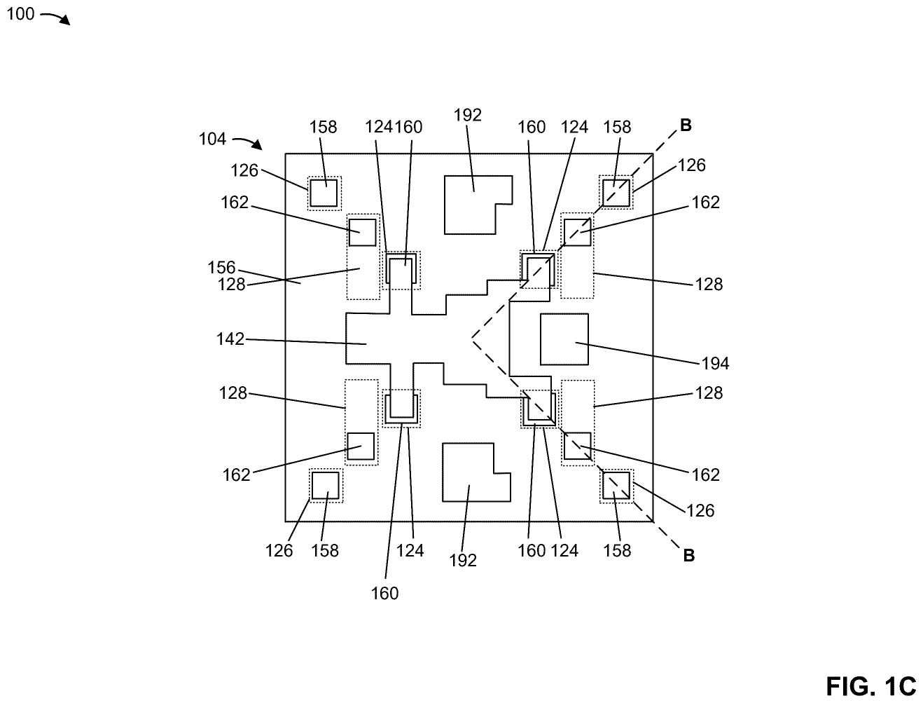

FIGS. 1A-1C are diagrams of an example image sensor device 100 described herein. The image sensor device 100 may include an example of a DoP image sensor device, which, as shown in a cross-section view in FIG. 1A, is an image sensor device that includes a sensor layer 102, a sensor circuitry layer 104 above the sensor layer 102, and an integrated circuit layer 106 above the sensor circuitry layer 104. Thus, the sensor layer 102, the sensor circuitry layer 104, and the integrated circuit layer 106 are stacked or vertically arranged in the image sensor device 100. The sensor layer 102 and the sensor circuitry layer 104 may be bonded at a bonding interface 108, and the sensor circuitry layer 104 and the integrated circuit layer 106 may be bonded at a bonding interface 110.

As shown in FIG. 1A, the sensor layer 102 includes a semiconductor substrate 112 and one or more photodetector regions 114 in the semiconductor substrate 112. Thus, the sensor layer 102 may be referred as a photodetector layer in that the photodetector regions 114 of the image sensor device 100 are included in the sensor layer 102. The semiconductor substrate 112 may include a bulk monocrystalline silicon (Si) substrate and/or another suitable semiconductor material substrate. The semiconductor substrate 112 may correspond to a portion of a semiconductor wafer (e.g., a sensor wafer) on which the sensor layer 102 was formed.

The photodetector regions 114 may each include a photodiode that is configured to sense photons of incident light and convert the photons to a photocurrent. For example, a photodetector region 114 may form a P-N junction with the semiconductor substrate 112 corresponding to a photodiode. A photodetector region 114 may include a deep collector region 116 and a shallow collector region 118 above the deep collector region 116. The deep collector region 116 and the shallow collector region 118 may have the same doping type, which is different form the doping type of the semiconductor substrate 112. For example, the deep collector region 116 and the shallow collector region 118 may each include one or more n-type dopants, whereas the semiconductor substrate 112 may include one or more p-type dopants. However, the deep collector region 116 and the shallow collector region 118 may have different doping concentrations of the same doping type. For example, the shallow collector region 118 may have a higher doping concentration than the deep collector region 116.

Deep cell wells 120 and shallow cell wells 122 may be included in the semiconductor substrate 112 and may surround individual photodetector regions 114 except for the bottom portions of the photodetector regions 114. The combination of the deep cell wells 120 and the shallow cell wells 122 provides optical isolation for the photodetector regions 114 and/or may contain the flow of photocurrent generated by the photodetector regions 114, thereby providing electrical isolation. The shallow cell wells 122 may be included over photodetector regions 114 and may be approximately perpendicular to the deep cell wells 120. The deep cell wells 120 may extend laterally alongside the sidewalls of the photodetector regions 114.

The deep cell wells 120 and shallow cell wells 122 may have the same doping type, which may be the same doping type as the semiconductor substrate 112 (e.g., a p-type dopant). However, the deep cell wells 120 and shallow cell wells 122 may have different doping concentrations of the same doping type. For example, the shallow cell wells 122 may have a higher doping concentration than the deep cell wells 120.

Respective floating diffusion nodes 124 may be included in the semiconductor substrate 112 above the photodetector regions 114. A floating diffusion node 124 may be configured to receive and temporarily store a photocurrent generated by an associated photodetector region 114. A floating diffusion node 124 may have the same dopant type as the deep collector region 116 and the shallow collector region 118 of the associated photodetector region 114.

Respective pickup regions 126 may also be included in the semiconductor substrate 112 above the photodetector regions 114. A pickup region 126 may be electrically coupled with the semiconductor substrate 112 and may have the same dopant type as the semiconductor substrate 112.

Transfer gates 128 extend into the photodetector regions 114, such as into the shallow collector region 118 of the photodetector regions 114. A transfer gate 128 may include an elongated portion that extends into a photodetector region 114, and a top portion on the semiconductor substrate 112. A transfer gate 128 may be configured to control the transfer of a photocurrent from an associated photodetector region 114 to an associated floating diffusion node 124. The transfer gate 128 may be selectively switched by applying a transfer voltage (Vₜₓ) to the transfer gate 128. A gate dielectric layer 130 is included between the transfer gates 128 and the semiconductor substrate 112, including between the transfer gates 128 and the associated photodetector regions 114. The gate dielectric layer 130 enables a conductive channel to be formed in the semiconductor substrate 112 between a photodetector region 114 and an associated floating diffusion node 124 without causing an associated transfer gate 128 to short circuit to the semiconductor substrate 112.

The transfer gates 128 may each include polysilicon, doped polysilicon, an electrically conductive metal or metal alloy such as tungsten (W), titanium nitride (TiN), titanium aluminum (TiAl), and/or another suitable gate material. The gate dielectric layer 130 may include one or more dielectric materials, such as a low dielectric constant (low-k) dielectric material (e.g., silicon oxide (SiOₓ such as SiO₂)), a high dielectric constant (high-k) dielectric material (e.g., hafnium oxide (HfOₓ such as HfO₂)), and/or another suitable gate dielectric material.

Sidewall spacers 132 may be included on the sidewalls of the top portions of the transfer gates 128. The sidewall spacers 132 may include one or more dielectric materials such as silicon oxide (SiOₓ), silicon nitride (SiₓN_{y} such as Si₃N₄), silicon oxynitride (SiON), and/or another suitable dielectric material.

A contact etch stop layer (CESL) 134 may be included over the transfer gates 128 and over the top side of the semiconductor substrate 112. A bonding dielectric layer 136 may be included on the CESL 134. The CESL 134 may facilitate etching of recesses through the bonding dielectric layer 136 for forming of contacts for the floating diffusion nodes 124, the pickup regions 126, and/or the transfer gates 128. The CESL 134 and the bonding dielectric layer 136 may each include one or more dielectric materials, such as a silicon oxide (SiOₓ), a silicon nitride (SiₓN_{y}), a silicon oxynitride (SiON), tetraethyl orthosilicate oxide, phosphosilicate glass (PSG), borophosphosilicate glass (BPSG), fluorinated silica glass (FSG), and/or carbon doped silicon oxide, among other examples.

As further shown in FIG. 1A, the sensor circuitry layer 104 also includes a bonding dielectric layer 138. The sensor layer 102 and the sensor circuitry layer 104 may be bonded at the bonding interface 108 in a dielectric-to-dielectric direct bond between the bonding dielectric layers 136 and 138. An active region dielectric layer 140 is included above the bonding dielectric layer 138. The active region dielectric layer 140 electrically isolates the sensor circuitry associated with the photodetector regions 114.

The sensor circuitry included in the sensor circuitry layer 104 may include source-follower gates 142, row-select gates (not shown in FIG. 1A-shown in FIG. 1C), and/or reset gates (not shown in FIG. 1A-shown in FIG. 1C). A source-follower gate 142 functions as a high impedance amplifier for the photodetector regions 114. A source-follower gate 142 may be electrically connected with a row-select gate, which is configured to control the flow of photocurrent to external circuitry. A reset gate may be configured to pull an associated floating diffusion node 124 to a high voltage (e.g., to a supply voltage) to “reset” the floating diffusion node 124 (e.g., by draining any residual charge in the floating diffusion node 124) prior to activation of an associated transfer gate 128 to transfer a photocurrent from an associated photodetector region 114 to the floating diffusion node 124.

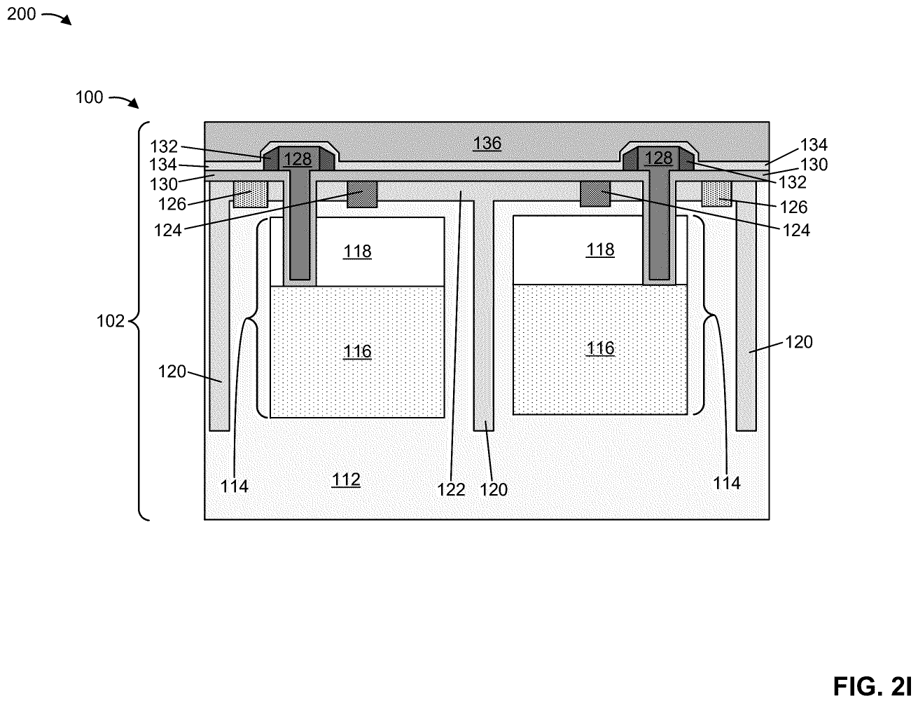

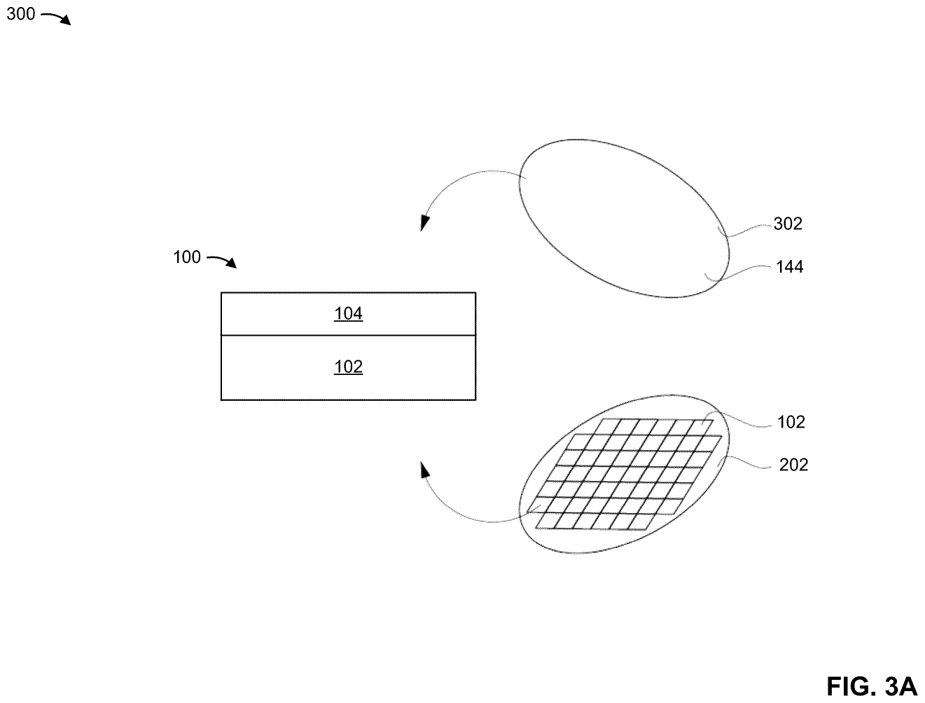

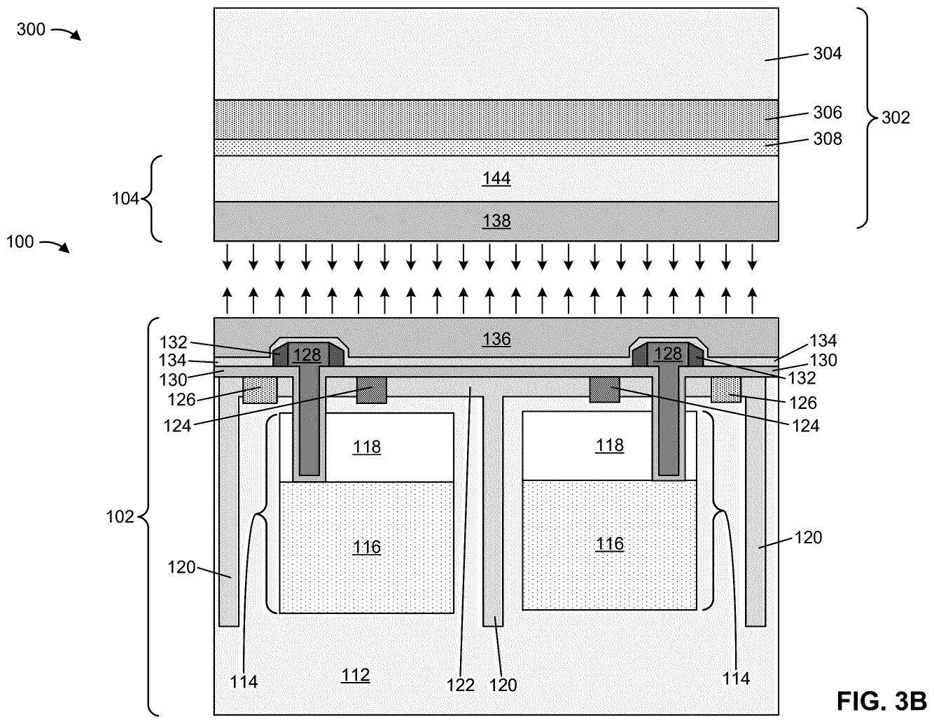

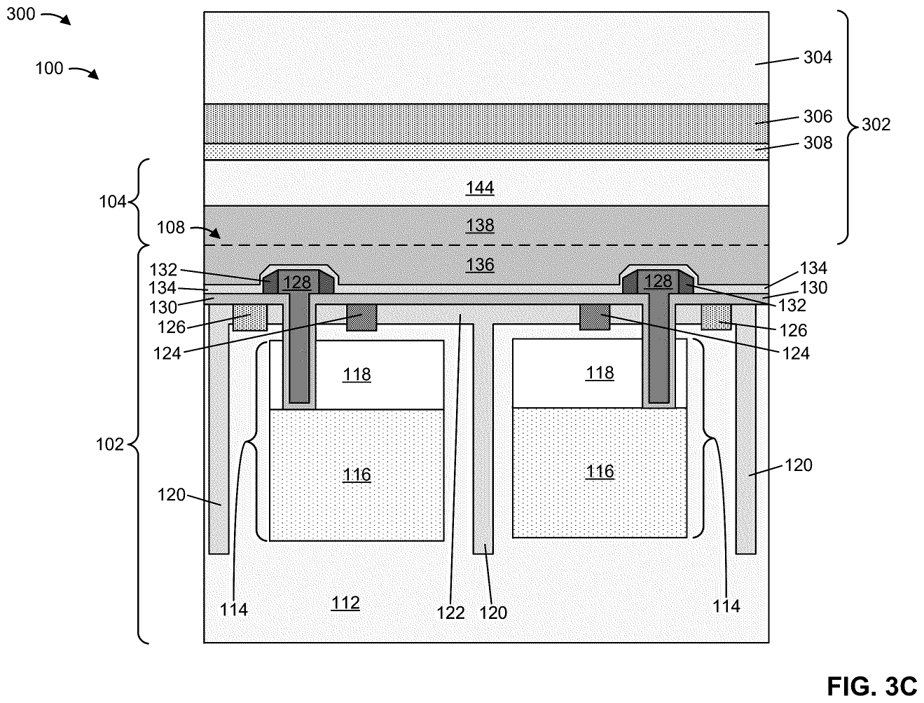

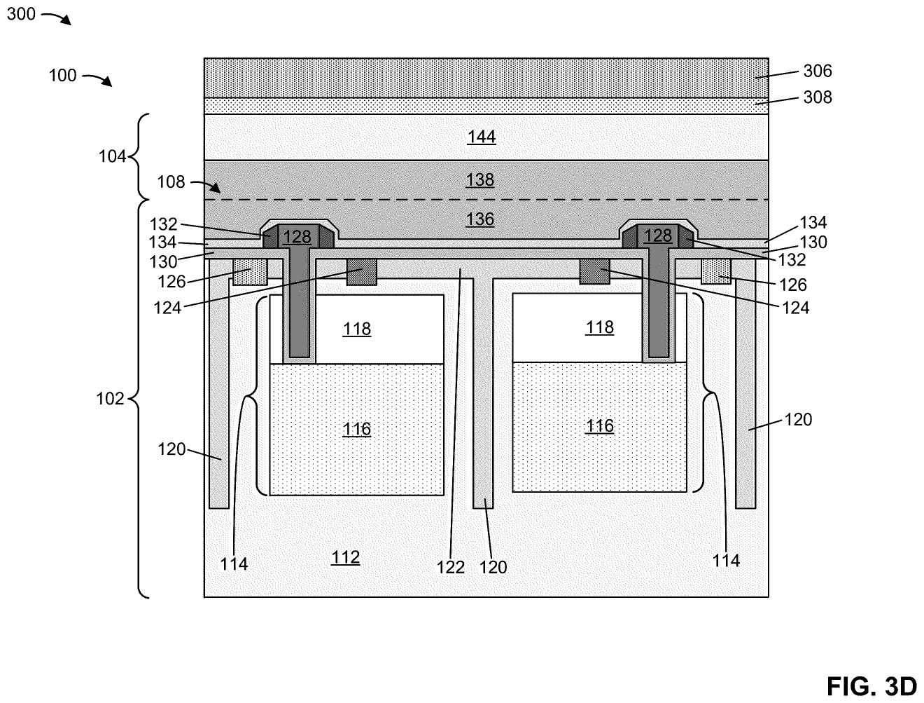

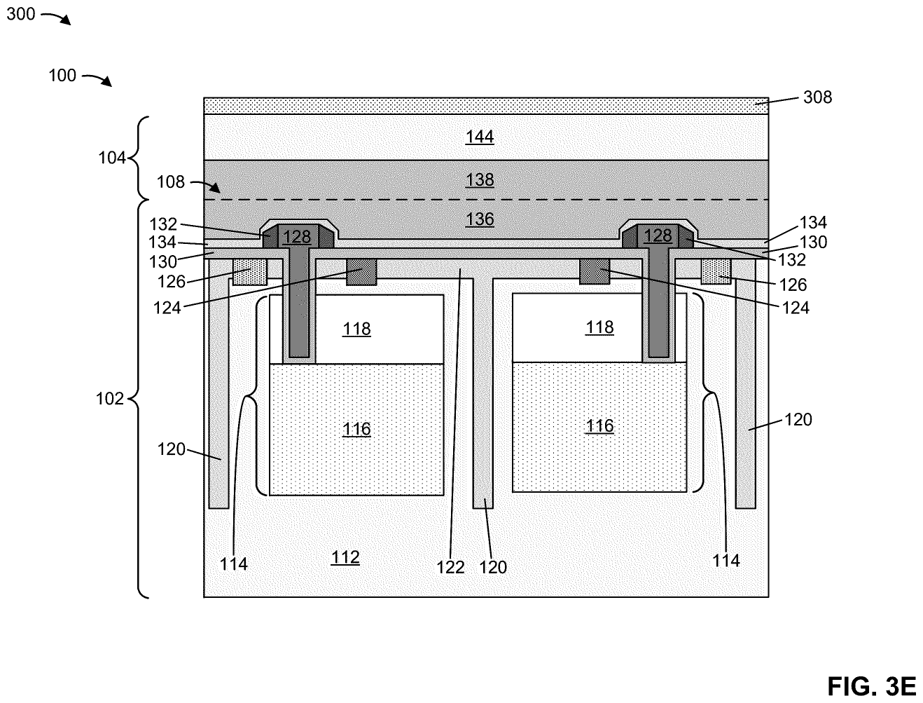

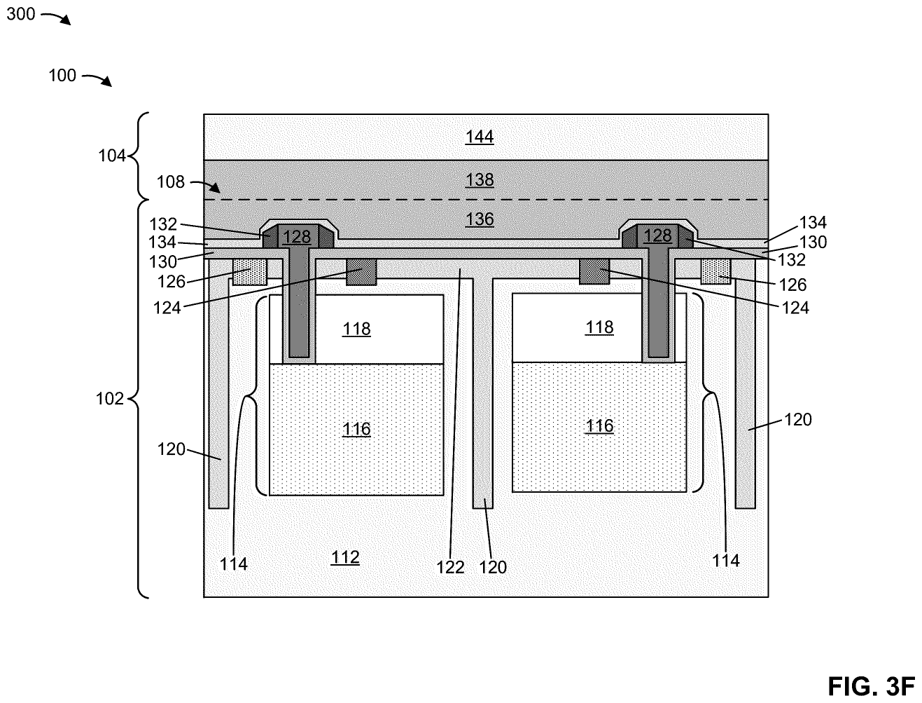

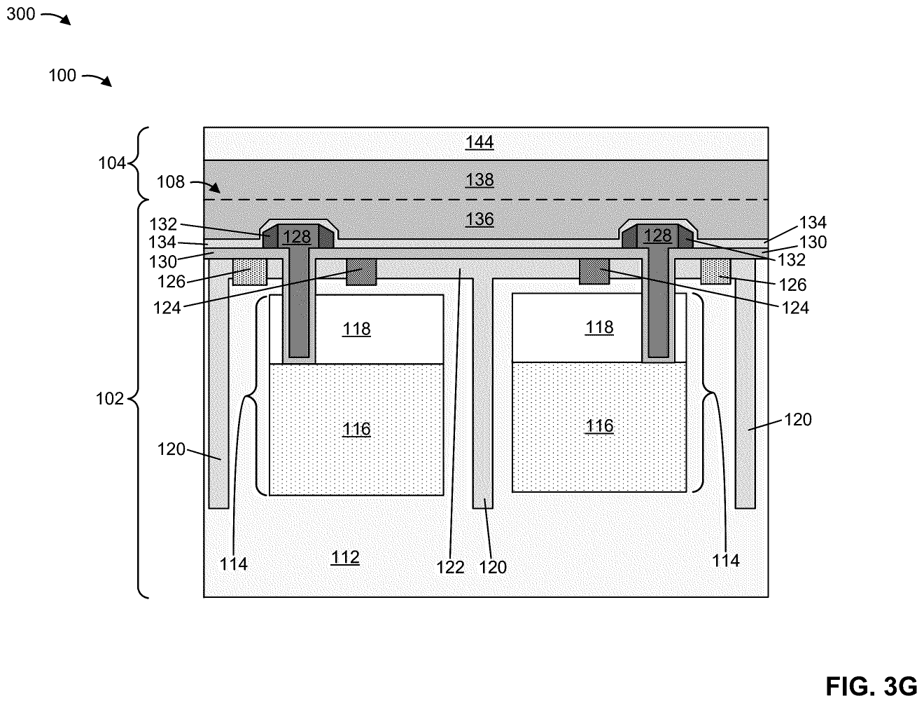

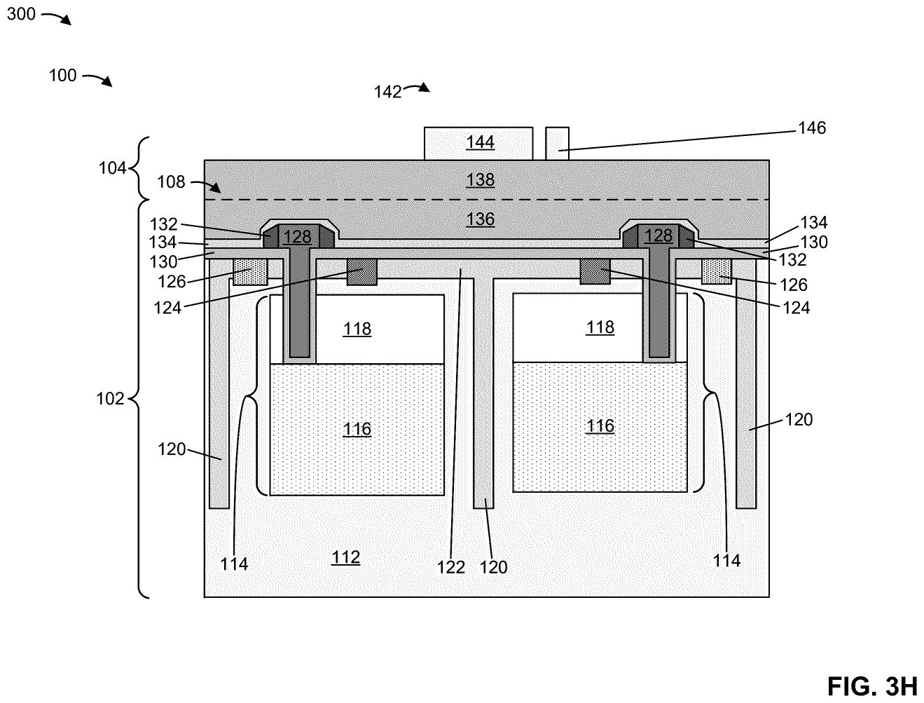

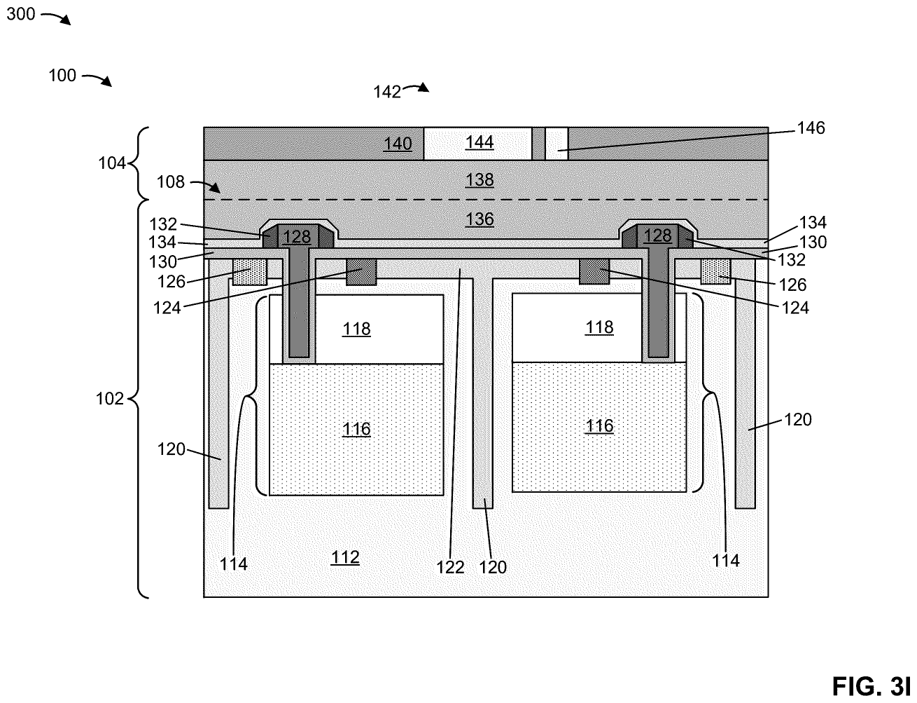

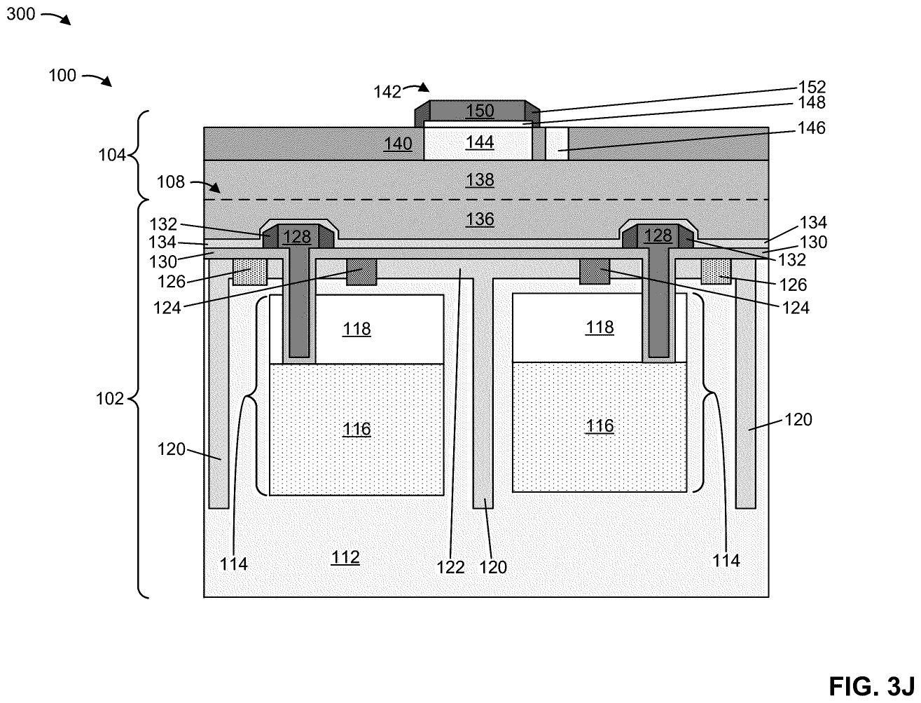

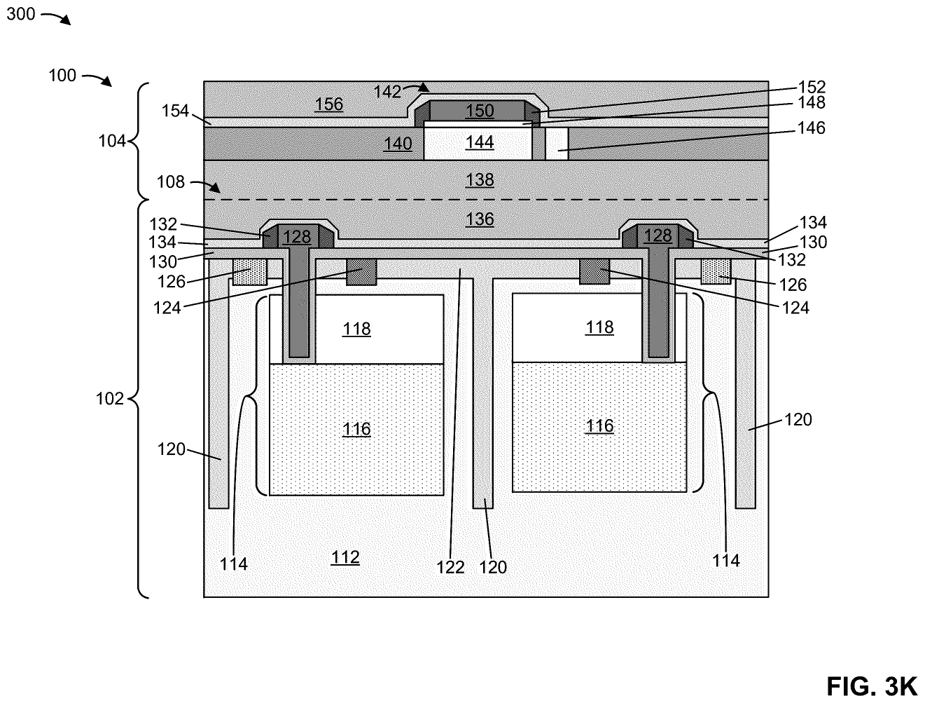

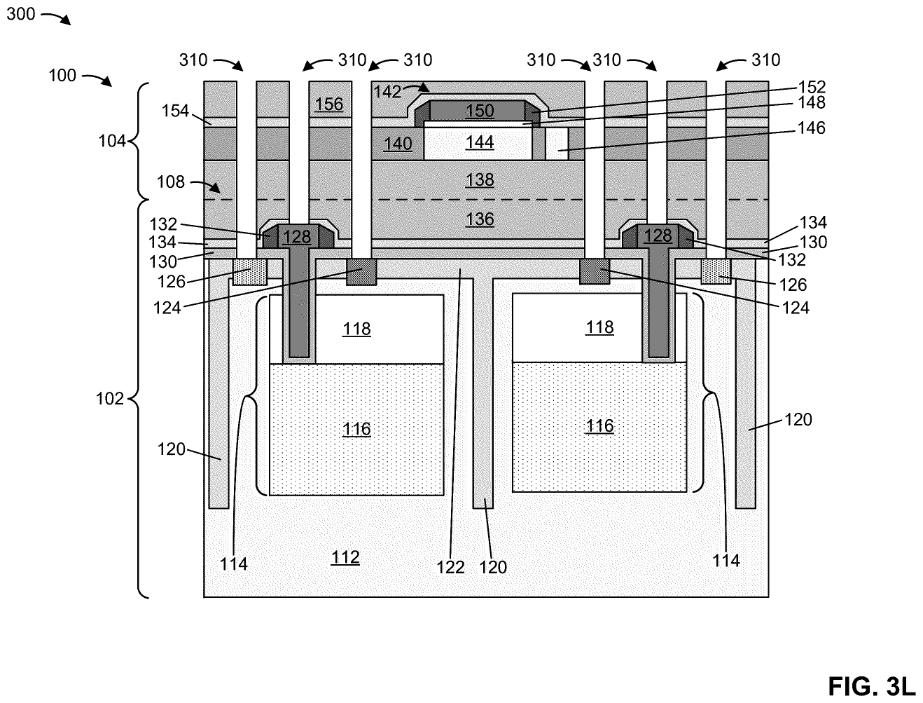

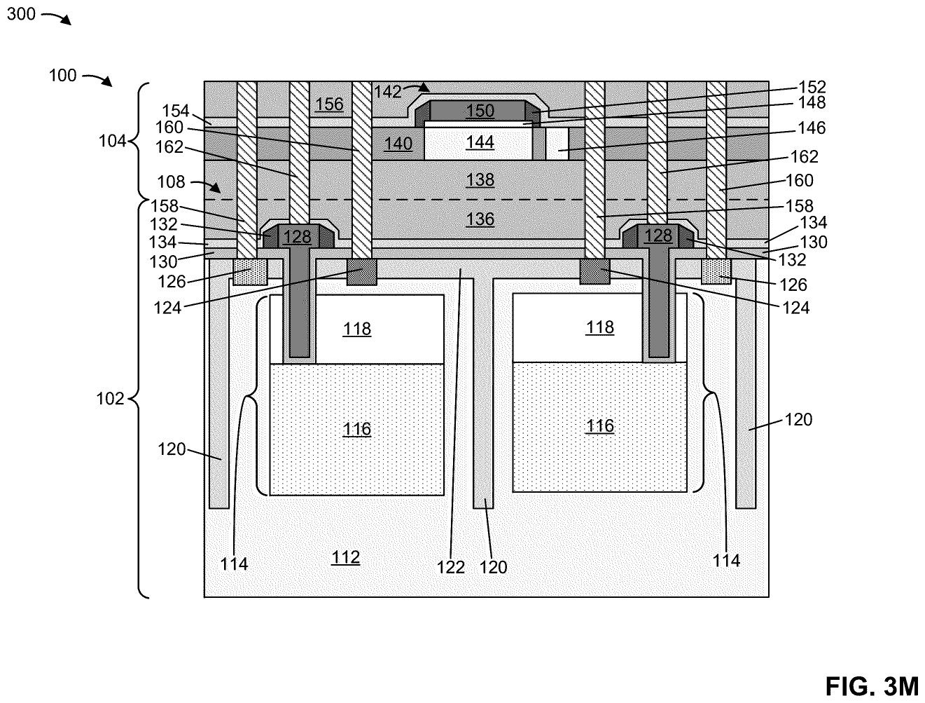

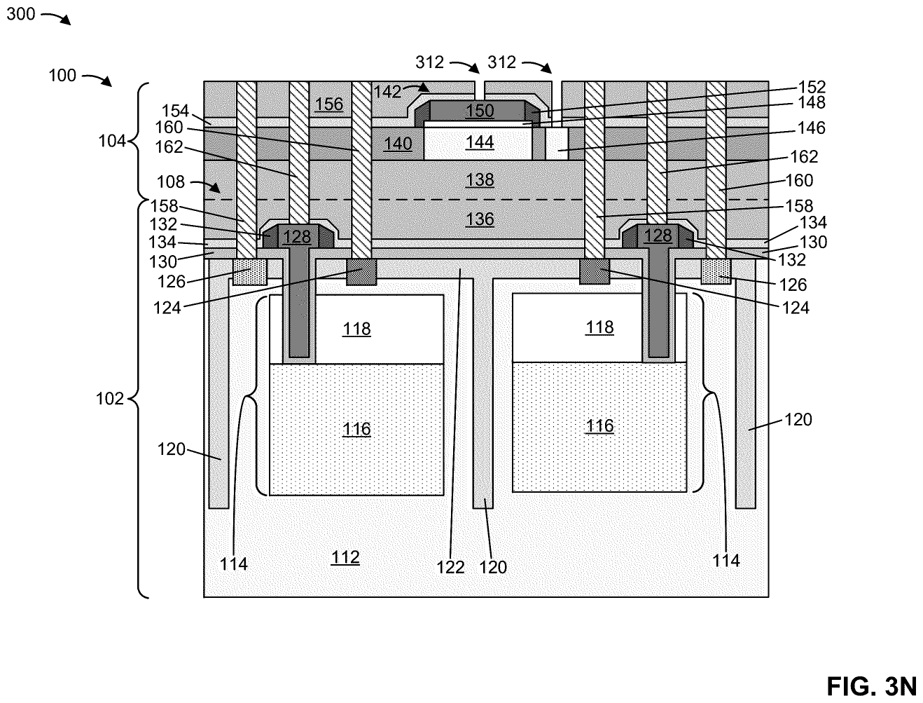

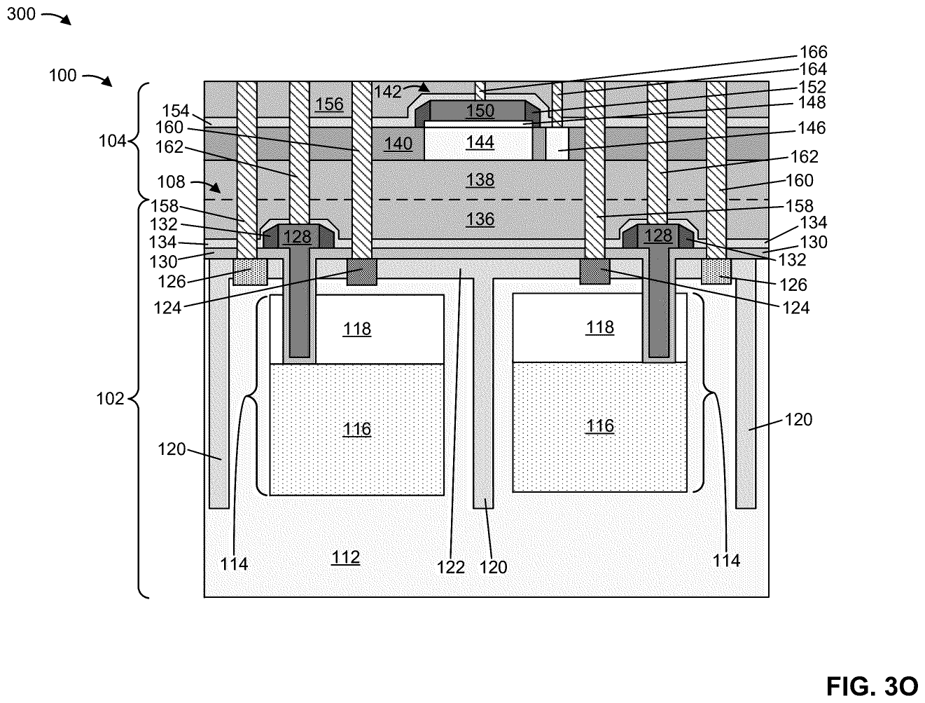

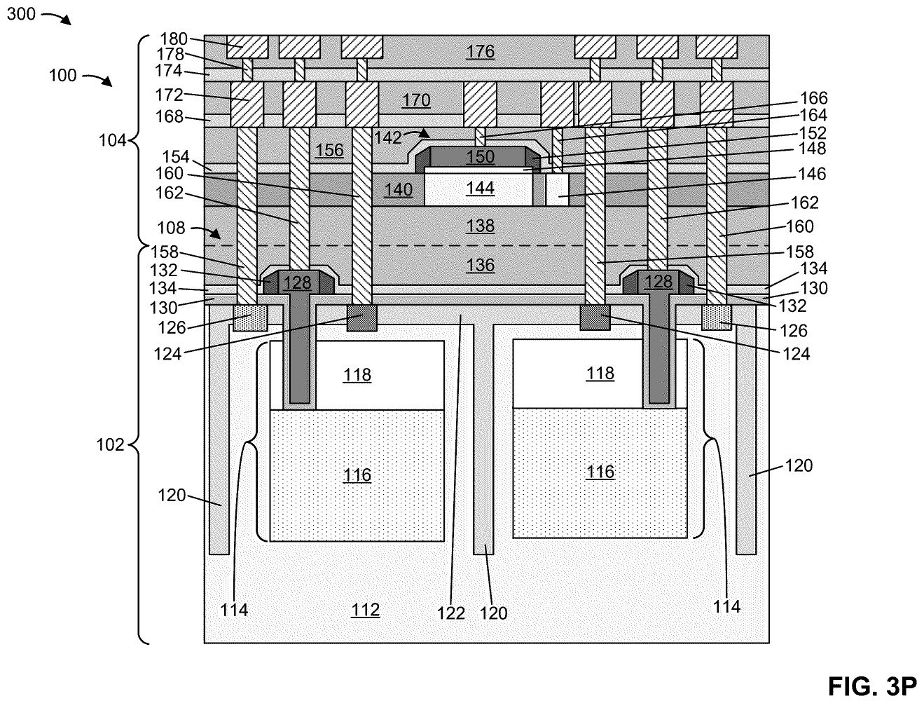

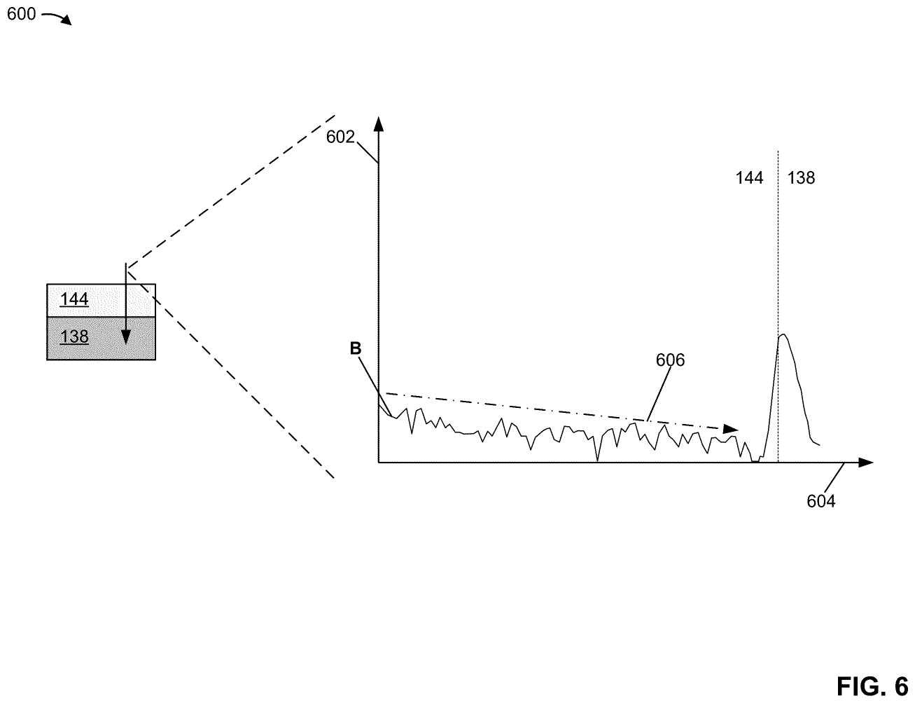

A source-follower gate 142 (or a row-select gate or a reset gate) may include a semiconductor layer 144 corresponding to a semiconductor channel layer. The semiconductor layer 144 may include a semiconductor material such as silicon (Si), silicon germanium (SiGe), and/or another suitable semiconductor material. In some implementations, the semiconductor layer 144 includes one or more types of dopants. As described in connection with FIGS. 3F and 6, the semiconductor layer 144 may contain a dopant that diffused into the semiconductor layer 144 from one or more etch stop layers by the processes that were used during the layer transfer of the semiconductor layer 144 to the image sensor device 100. The dopant may include a p-type dopant such as boron (B), gallium (Ga), and/or indium (In), among other examples. Additionally and/or alternatively, the dopant may include an n-type dopant such as phosphorus (P) and/or arsenic (As), among other examples. The processes used to transfer the semiconductor layer 144 to the image sensor device 100 may result in a particular dopant profile in the semiconductor layer 144. For example, a dopant concentration gradient may occur in the semiconductor layer 144, where the dopant concentration in the semiconductor layer 144 is greater at the top of the semiconductor layer 144 and lowest at the bottom of the semiconductor layer 144. The higher dopant concentration at the top of the semiconductor layer 144 may occur because dopants in etch stop layers above the semiconductor layer 144 may diffuse into the semiconductor layer 144 through the top of the semiconductor layer 144. The etch stop layers are used to transfer the semiconductor layer 144 to the image sensor device 100. As described in greater detail in connection with FIGS. 3B and 3C, the etch stop layers enable low-temperature processes such as wafer grinding and etching to be used to remove a semiconductor substrate, on which the semiconductor layer 144 was formed, after the semiconductor layer 144 is transferred to the image sensor device 100. In some implementations, the dopant concentration at the top of the semiconductor layer 144 may be greater than or approximately equal to 3×10¹⁵ dopant atoms (e.g., boron atoms, phosphorous atoms) per cubic centimeter. However, other values and ranges are within the scope of the present disclosure.

The source-follower gate 142 (or the row-select gate or the reset gate) may control the flow of current through the semiconductor channel layer to a source/drain region 146 in the semiconductor layer 144. A gate dielectric layer 148 may be included between the source-follower gate 142 (or the row-select gate or the reset gate) and the semiconductor layer 144. The source-follower gate 142 (or the row-select gate or the reset gate) may include a gate electrode 150 and sidewall spacers 152 on the sidewalls of the gate electrode 150. The gate dielectric layer 148, the gate electrode 150, and/or the sidewall spacers 152 of the source-follower gate 142 (or the row-select gate or the reset gate) may be similar to the transfer gates 128 or may be different.

Another CESL 154 may be included over the source-follower gate 142 (or the row-select gate or the reset gate), and another dielectric layer 156 may be included over the CESL 154. As shown in FIG. 1A, various contacts may extend through one or more layers of the sensor layer 102 and/or one or more layers of the sensor circuitry layer 104. A pickup contact 158 may extend through the gate dielectric layer 130, through the CESL 134, through the bonding dielectric layers 136 and 138, through the active region dielectric layer 140, through the CESL 154, and through the dielectric layer 156 to a pickup region 126. A floating diffusion contact 160 may extend through the gate dielectric layer 130, through the CESL 134, through the bonding dielectric layers 136 and 138, through the active region dielectric layer 140, through the CESL 154, and through the dielectric layer 156 to a floating diffusion node 124. A gate contact 162 may extend through the gate dielectric layer 130, through the CESL 134, through the bonding dielectric layers 136 and 138, through the active region dielectric layer 140, through the CESL 154, and through the dielectric layer 156 to a transfer gate 128. A source/drain contact 164 may extend through the dielectric layer 156 and through the CESL 154 to the source/drain region 146. A gate contact 166 may extend through the dielectric layer 156 and through the CESL 154 to the source-follower gate 142 (or the row-select gate or the reset gate).

The contacts 158-166 may each include vias, plugs, and/or another type of elongated electrically conductive structures. The contacts 158-166 may each include tungsten (W), cobalt (Co), ruthenium (Ru), titanium (Ti), aluminum (Al), and/or gold (Au), among other electrically conductive materials.

Another etch stop layer 168 and another dielectric layer 170 may be included above the dielectric layer 156. Metallization layers 172 may be included in the etch stop layer 168 and/or in the dielectric layer 170 and may electrically connect with one or more of the contacts 158-166. The metallization layers 172 and the contacts 158-166 enable the floating diffusion nodes 124, the pickup regions 126, the transfer gates 128, the source-follower gates 142, the row-select gates, the reset gates, and/or other integrated circuit devices in the image sensor devices 100 to be electrically interconnected. The metallization layers 172 may each include a combination of trenches, conductive traces, and/or other types of conductive structures. The metallization layers 172 may each include tungsten (W), cobalt (Co), ruthenium (Ru), titanium (Ti), aluminum (Al), and/or gold (Au), among other electrically conductive materials. In some implementations, the sensor circuitry layer 104 includes a plurality of vertically arranged metallization layers 172 and interconnect layers.

As further shown in FIG. 1A, the sensor circuitry layer 104 includes another etch stop layer 174 and a bonding dielectric layer 176. Bonding vias 178 and bonding pads 180 may be included in the etch stop layer 174 and/or in the bonding dielectric layer 176. The bonding vias 178 and the bonding pads 180 may each include tungsten (W), cobalt (Co), ruthenium (Ru), titanium (Ti), aluminum (Al), copper (Cu), gold (Au), and/or a combination thereof, among other examples of electrically conductive metals. The bonding vias 178 and the bonding pads 180 may enable signals and/or power to be routed between the sensor circuitry layer 104 and the integrated circuit layer 106.

The integrated circuit layer 106 may include a device layer 182 and one or more integrated circuit devices 184 in the device layer 182. The integrated circuit devices 184 may include transistors (e.g., planar transistors, fin field effect transistors (finFETs), gate all around (GAA) transistors), capacitors, resistors, inductors, and/or other types of passive and/or active integrated circuit devices. The integrated circuit devices 184 may correspond to logic circuitry of the image sensor device 100. Thus, the integrated circuit layer 106 may be referred to as a logic layer or a system on chip (SoC) layer. Additionally and/or alternatively, the integrated circuit devices 184 may correspond to power supply circuitry, input/output (I/O) circuitry, and/or another type of integrated circuitry.

As further shown in FIG. 1A, the integrated circuit layer 106 includes bonding vias 186 and bonding pads 188 coupled to the bonding vias 186. At the bonding interface 110 between the sensor circuitry layer 104 and the integrated circuit layer 106, the bonding pads 180 and 188 are bonded together in metal-to-metal bonds, and the bonding dielectric layer 176 is bonded to a dielectric layer of the device layer 182 in a dielectric-to-dielectric bond.

FIG. 1B illustrates an example layout view of the sensor layer 102 at the location of the line A-A in FIG. 1A. FIG. 1B illustrates the location of the cross-section view along line-A-A in FIG. 1A. As shown in FIG. 1B, the sensor layer 102 may include one or more pixel sensors 190. A pixel sensor 190 may include a photodetector region 114, a floating diffusion node 124, a pickup region 126, and a transfer gate 128. In some implementations, a plurality of pixel sensors 190 share the same floating diffusion node 124.

FIG. 1C illustrates an example layout view of the sensor circuitry layer 104 at the location of the line B-B in FIG. 1A. FIG. 1C illustrates the location of the cross-section view along line-B-B in FIG. 1A. As shown in FIG. 1C, the floating diffusion nodes 124 of the pixel sensors 190 are connected to floating diffusion contacts 160. The pickup regions 126 of the pixel sensors 190 are connected to pickup contacts 158. The transfer gates 128 of the pixel sensors 190 are connected to gate contacts 162. The source-follower gate 142 may be connected to floating diffusion contacts 160 that are connected to the floating diffusion nodes 124 of the pixel sensors 190. Row-select gates 192 and reset gates 194 may also be included in the sensor circuitry layer 104.

As indicated above, FIGS. 1A-1C are provided as an example. Other examples may differ from what is described with regard to FIGS. 1A-1C.

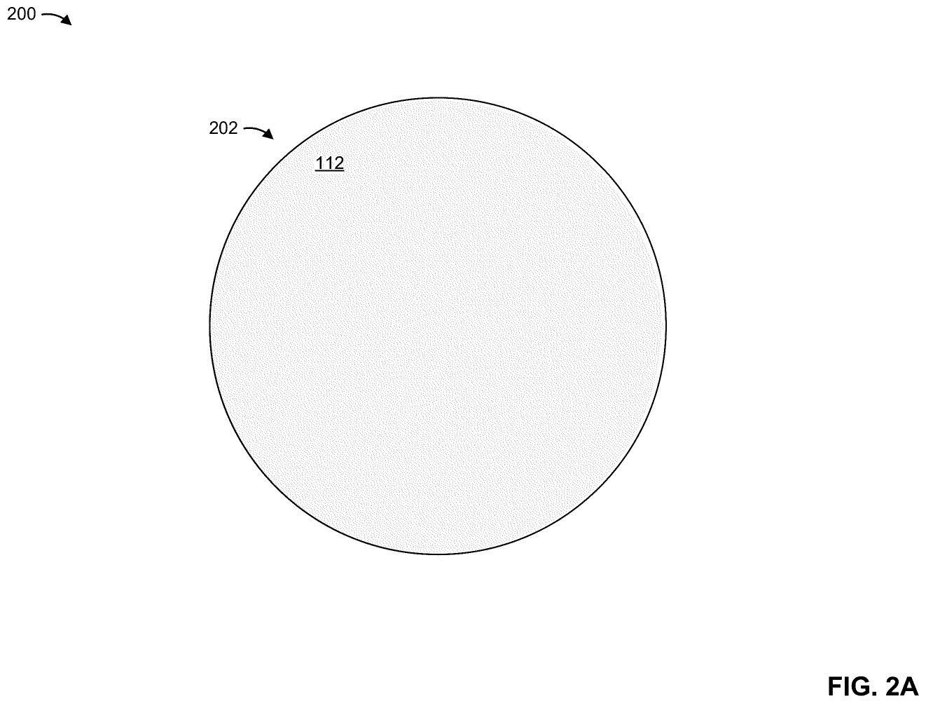

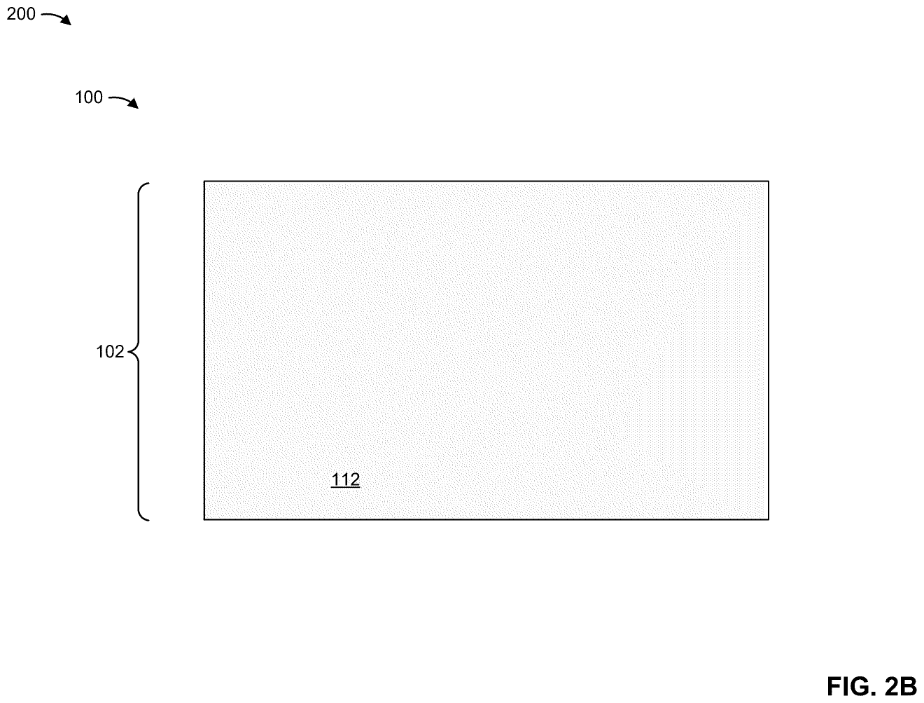

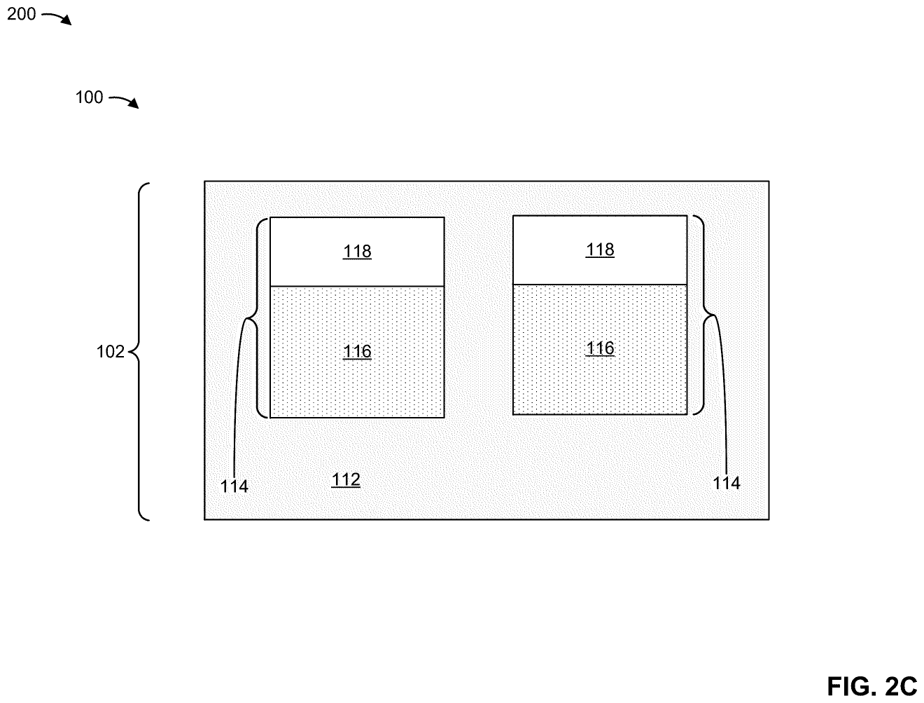

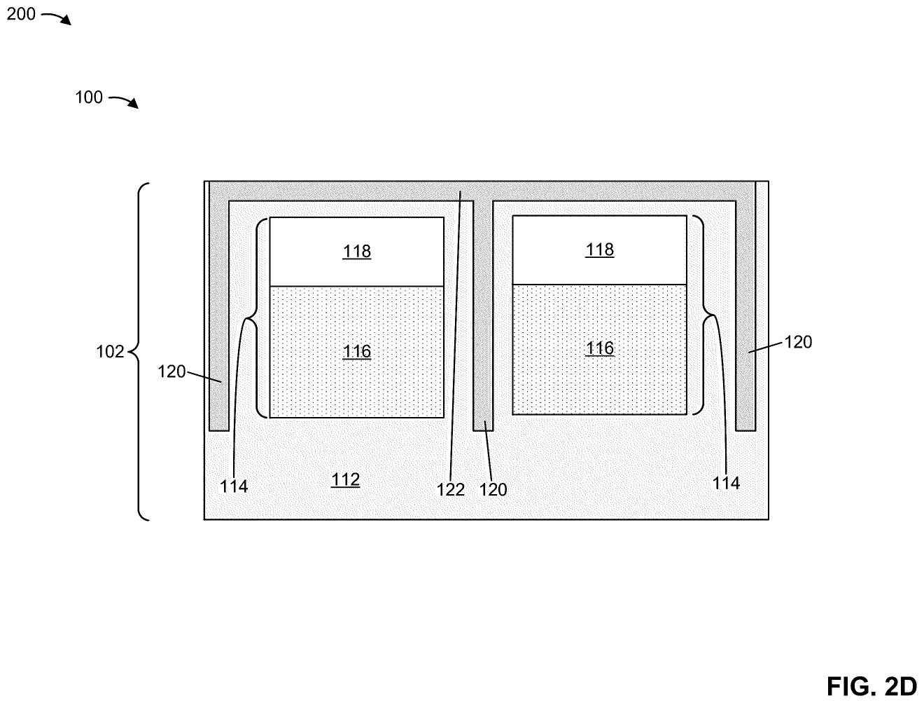

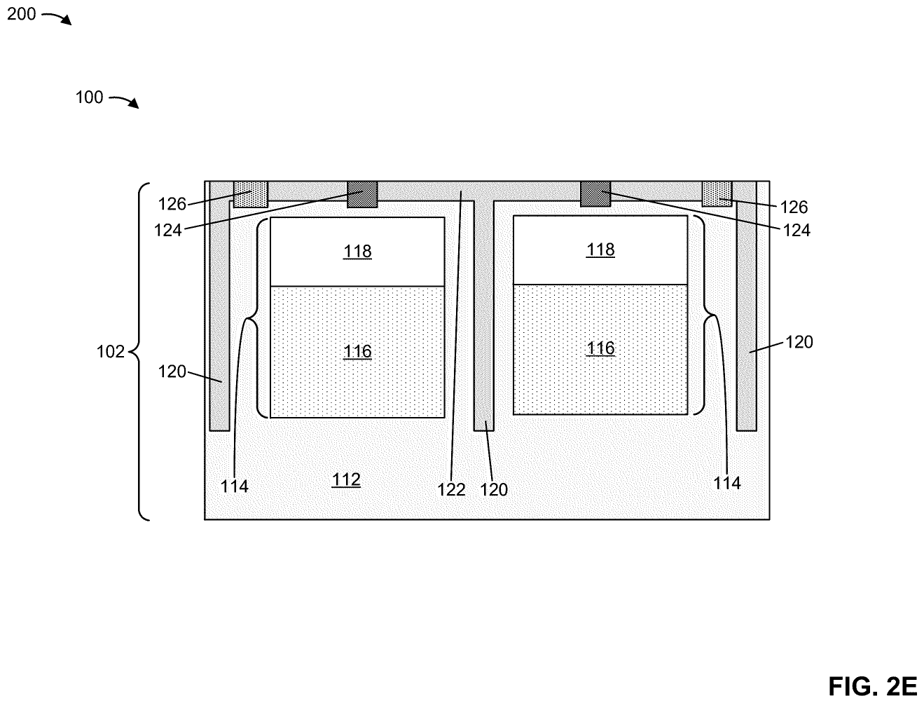

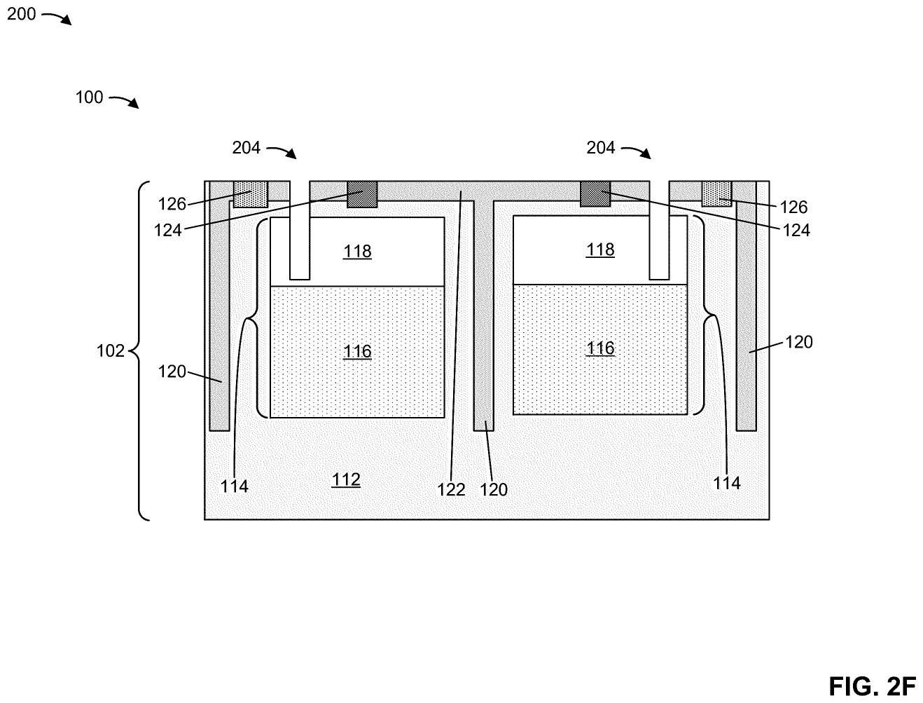

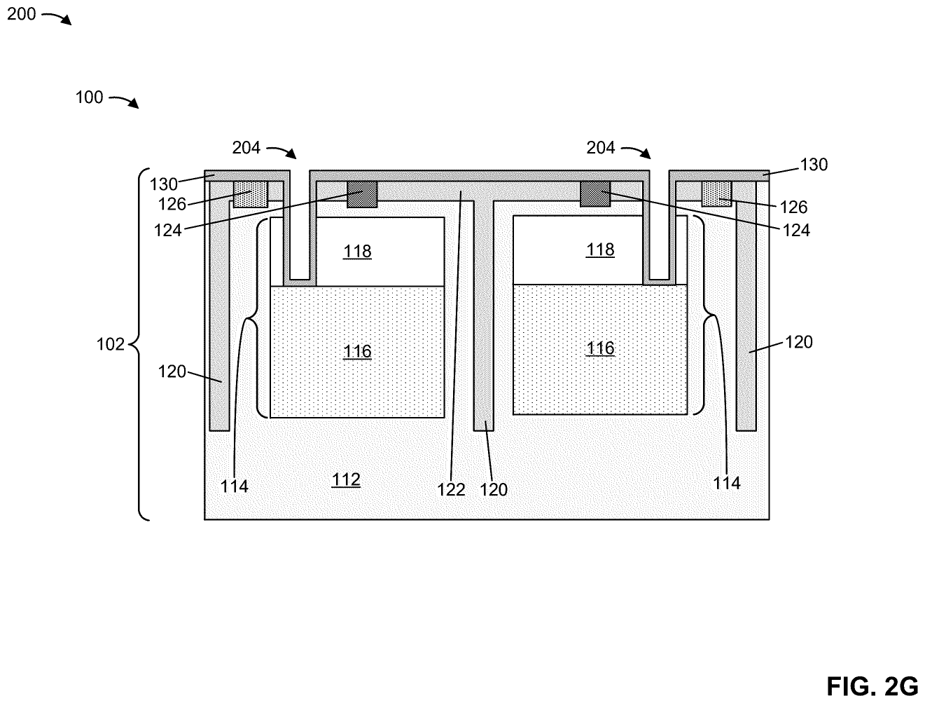

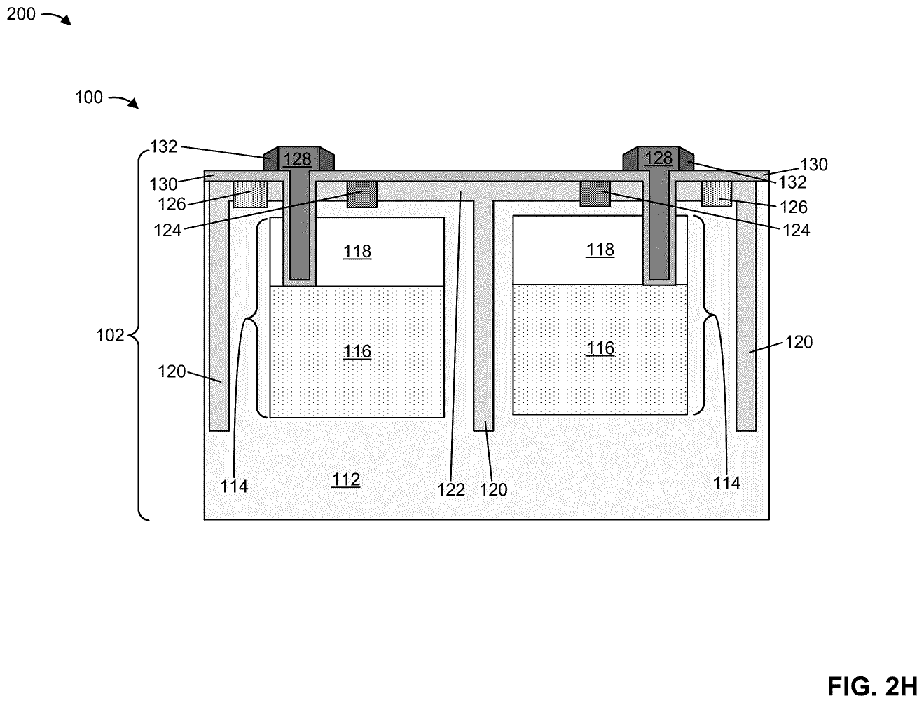

FIGS. 2A-2I are diagrams of an example 200 of forming sensor layers 102 of image sensor devices 100 formed on a sensor wafer 202. In some implementations, one or more operations described in connection with FIGS. 2A-2I are performed using one or more semiconductor processing tools, such as a deposition tool, an exposure tool, a developer tool, an etch tool, a planarization tool, an ion implantation tool, and/or a wafer/die transport tool, among other examples.

Turning to FIGS. 2A and 2B, the sensor wafer 202 may be provided. The sensor wafer 202 may correspond to and/or may include the semiconductor substrate 112 of the image sensor devices 100. The operations described in connection with FIGS. 2A-21 may be performed at the wafer level in the image sensor devices 100 may be processed together on the sensor wafer 202. Alternatively, individual image sensor devices 100 may be processed using techniques described in connection with FIGS. 2A-2I.

As shown in FIG. 2C, an ion implantation tool and/or another type of semiconductor processing tool may be used to dope the semiconductor substrate 112 of the image sensor devices 100 on the sensor wafer 202 with one or more types of dopants to form the deep collector regions 116 and the shallow collector regions 118 of the photodetector regions 114 of the sensor layers 102 of the image sensor devices 100. In some implementations, an implant mask is formed on the semiconductor substrate 112 to enable specific regions of the semiconductor substrate 112 to be doped with ions to form the deep collector regions 116 and the shallow collector regions 118 of the photodetector regions 114. In some implementations, the deep collector regions 116 formed first, and the shallow collector regions 118 are formed above the deep collector regions 116. In some implementations, the shallow collector regions 118 are formed first, and deep collector regions 116 are formed below the shallow collector regions 118.

As shown in FIG. 2D, an ion implantation tool and/or another type of semiconductor processing tool may be used to dope the semiconductor substrate 112 of the image sensor devices 100 on the sensor wafer 202 with one or more types of dopants to form the deep cell wells 120 and the shallow cell wells 122 around the photodetector regions 114 of the sensor layers 102 of the image sensor devices 100. In some implementations, an implant mask is formed on the semiconductor substrate 112 to enable specific regions of the semiconductor substrate 112 to be doped with ions to form the deep cell wells 120 and the shallow cell wells 122. In some implementations, the deep cell wells 120 and formed first, and the shallow cell wells 122 are formed above the deep cell wells 120. In some implementations, the shallow cell wells 122 are formed first, and deep cell wells 120 are formed below the shallow cell wells 122.

As shown in FIG. 2E, an ion implantation tool and/or another type of semiconductor processing tool may be used to dope the semiconductor substrate 112 of the image sensor devices 100 on the sensor wafer 202 with one or more types of dopants to form the floating diffusion nodes 124 and the pickup regions 126 above the photodetector regions 114 of the sensor layers 102 of the image sensor devices 100. In some implementations, an implant mask is formed on the semiconductor substrate 112 to enable specific regions of the semiconductor substrate 112 to be doped with ions to form the floating diffusion nodes 124 and the pickup regions 126.

In some implementations, the semiconductor substrate 112 may be doped with a first dopant type (e.g., an n-type dopant) to form the deep collector regions 116, the shallow collector regions 118, and the floating diffusion nodes 124. The semiconductor substrate 112 may be doped with a second dopant type (e.g., a p-type dopant) to form the deep cell wells 120, the shallow cell wells 122, and the pickup regions 126.

As shown in FIG. 2F, recesses 204 may be formed in the semiconductor substrate 112 of the sensor layers 102 of the image sensor devices 100. The recesses 204 may extend into a portion of the photodetector regions 114, such as into the shallow collector regions 118 of the photodetector regions 114. A recess 204 may be formed between a floating diffusion node 124 and a pickup region 126.

In some implementations, a pattern in a photoresist layer is used to etch the semiconductor substrate 112 to form the recesses 204. In these implementations, a deposition tool may be used to form the photoresist layer on the semiconductor substrate 112. An exposure tool may be used to expose the photoresist layer to a radiation source to pattern the photoresist layer. A developer tool may be used to develop and remove portions of the photoresist layer to expose the pattern. An etch tool may be used to etch the semiconductor substrate 112 based on the pattern to form the recesses 204. In some implementations, the etch operation includes dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the semiconductor substrate 112 based on a pattern.

As shown in FIG. 2G, a gate dielectric layer 130 may be deposited over the semiconductor substrate 112 of the sensor layers 102 of the image sensor devices 100. The gate dielectric layer 130 is also conformally deposited in the recesses 204 such that the gate dielectric layer 130 is formed on the sidewalls and the bottom surfaces of the recesses 204. In some implementations, a deposition tool is used to deposit the gate dielectric layer 130 using a conformal deposition technique such as chemical vapor deposition (CVD) and/or atomic layer deposition (ALD), among other examples.

As shown in FIG. 2H, the transfer gates 128 and associated sidewall spacers 132 are formed in the sensor layers 102 of the image sensor devices 100. Portions of the transfer gates 128 are formed on the gate dielectric layer 130 in the recesses 204, and other portions of the transfer gates 128 extend above the recesses 204. The sidewalls spacers 132 are formed on the other portions of the transfer gates 128 extend above the recesses 204.

To form the transfer gates 128, a deposition tool may be used to deposit the material of the transfer gates 128 in a blanket layer using a CVD technique, a physical vapor deposition (PVD) technique, an electroplating technique, and/or another suitable deposition technique. In some implementations, a planarization tool may be used to perform a planarization operation such as a chemical mechanical planarization (CMP) operation to planarize the blanket layer. The blanket layer may then be patterned and etched to remove material from the blanket layer to form the transfer gates 128. In some implementations, the sidewall spacers 132 may be formed using similar techniques.

As shown in FIG. 2I, the CESL 134 is deposited over the transfer gates 128 and over the top of the semiconductor substrate 112. In some implementations, a deposition tool is used to deposit the CESL 134 using a conformal deposition technique such as CVD and/or ALD, among other examples. The bonding dielectric layer 136 may then be deposited on the CESL 134 using a CVD technique, a PVD technique, an oxidation technique, and/or another suitable deposition technique. In some implementations, a planarization tool may be used to perform a planarization operation such as a CMP operation to planarize the bonding dielectric layer 136.

As indicated above, FIGS. 2A-2I are provided as an example. Other examples may differ from what is described with regard to FIGS. 2A-2I.

FIGS. 3A-3P are diagrams of an example 300 of forming sensor circuitry layers 104 of image sensor devices 100 formed on a sensor wafer 202. In some implementations, one or more operations described in connection with FIGS. 3A-3P are performed using one or more semiconductor processing tools, such as a deposition tool, an exposure tool, a developer tool, an etch tool, a planarization tool, an ion implantation tool, a bonding tool, and/or a wafer/die transport tool, among other examples. In some implementations, one or more of the operations described in connection with FIGS. 3A-3P may be performed after forming the sensor layers 102 of the image sensor devices 100, as described in connection with FIGS. 2A-2I.

As shown in FIG. 3A, a layer stack 302 including the semiconductor layer 144 may be bonded to the sensor wafer 202 such that the semiconductor layer 144 of the sensor circuitry layer 104 is bonded to the sensor layers 102 of the image sensor devices 100 on the sensor wafer 202.

As shown in FIGS. 3B and 3C, a bonding tool may be used to bond the layer stack 302 to the sensor layers 102 by forming a dielectric-to-dielectric bond between the bonding dielectric layer 136 of the sensor layers 102 and the bonding dielectric layer 138 of the layer stack 302. The bonding dielectric layer 138 and the semiconductor layer 144 of the sensor circuitry layers 104 may be supported on (and included as part of) the layer stack 302. For example, the layer stack 302 may include a semiconductor substrate 304 (e.g., a carrier substrate formed of a semiconductor layer), an etch stop layer 306 on the semiconductor substrate 304, an etch stop layer 308 on the etch stop layer 306, the semiconductor layer 144 on the etch stop layer 308, and the bonding dielectric layer 138 on the semiconductor layer 144.

The etch stop layer 306 may be formed on the semiconductor substrate 304 (e.g., by doping a portion of the semiconductor substrate 304 or epitaxially growing the etch stop layer 306 on the semiconductor substrate 304). The etch stop layer 308 may be formed on the etch stop layer 306 (e.g., by epitaxially growing the etch stop layer 308 on the etch stop layer 306). The semiconductor layer 144 may be formed on the etch stop layer 308 (e.g., by epitaxially growing the semiconductor layer 144 on the etch stop layer 308). The bonding dielectric layer 138 may be deposited on the semiconductor layer 144 (e.g., using a CVD technique, a PVD technique, an oxidation technique). The layer stack 302 may then be flipped over and bonded to the sensor layers 102 of the image sensor devices 100 with the bonding dielectric layer 138 facing the bonding dielectric layer 136.

In some implementations, the semiconductor substrate 304 includes undoped silicon (Si) and/or another semiconductor material. In some implementations, the etch stop layer 306 includes silicon doped with one or more types of dopants such as p-type dopants including boron (B) and/or gallium (Ga), among other examples. In some implementations, the etch stop layer 308 includes silicon doped with one or more types of dopants such as p-type dopants including boron (B) and/or gallium (Ga), among other examples. The dopant concentration in the etch stop layer 306 may be greater than the dopant concentration in the etch stop layer 308 to provide etch selectivity between the etch stop layer 306 and the etch stop layer 308. Including multiple etch stop layers that have etch selectivity enables the process of removing the layer stack 302 to be highly controlled. The layer stack 302 can be removed in a layer-by-layer sequence in which thinner layers are sequentially removed (e.g., the etch stop layer 306 is removed, followed by the etch stop layer 308) as opposed to etching a single bulk layer. Etching through multiple thinner layers in a sequential manner enables the material to be removed from the layers in a highly uniform manner so that the surface uniformity can be maintained for the layers, and so that a high surface uniformity can be achieved for the semiconductor layer 144.

In some implementations, the etch stop layer 308 includes silicon germanium (SiGe) or silicon germanium (SiGe) doped with one or more p-type dopants such as boron (SiGe:B) and/or gallium (SiGe:Ga), among other examples. In some implementations, the etch stop layer 308 includes a different type of dopant (e.g., a n-type dopant) than the doping of the etch stop layer 306. In some implementations, an additional boron-doped silicon germanium layer is included between the etch stop layer 308 and the semiconductor layer 144.

In some implementations, the thickness of the etch stop layer 306 and the thickness of the etch stop layer 308 are approximately the same thickness. In some implementations, the thickness of the etch stop layer 306 is greater than the thickness of the etch stop layer 308. In some implementations, the thickness of the etch stop layer 308 is greater than the thickness of the etch stop layer 306. In some implementations, the thickness of the etch stop layer 306 and the thickness of the etch stop layer 308 are based on the types of etchants that are to be used to etch the etch stop layer 306 and the etch stop layer 308. For example, the thickness of the etch stop layer 306 and the thickness of the etch stop layer 308 may be based on the etch rate of the etch stop layer 306 and/or the etch rate of the etch stop layer 308 provided by the etchants. As another example, the thickness of the etch stop layer 306 and the thickness of the etch stop layer 308 may be based on the etch selectivity of the etchants.

In some implementations, if the etch stop layer 306 is too thin, the etch stop layer 306 may be etched through prematurely, resulting in a non-uniform thickness in the etch stop layer 308. In some implementations, if the etch stop layer 306 is too thick, the etch stop layer 306 may not be etched through fully, resulting in residual material that causes the etch stop layer 308 to be etched non-uniformly. In some implementations, if the etch stop layer 308 is too thin, the etch stop layer 308 may be etched through prematurely, resulting in a non-uniform thickness in the semiconductor layer 144.

As shown in FIG. 3D, the semiconductor substrate 304 is removed from the image sensor devices 100. In some implementations, a wafer grinding tool is used to perform a planarization operation such as a wafer grinding operation to grind away material from the semiconductor substrate 304 to remove the semiconductor substrate 304. In some implementations, an etch tool is used to perform an etch operation to etch the semiconductor substrate 304 to remove the semiconductor substrate 304. The wafer grinding operation and/or the etch operation for the semiconductor substrate 304 stops on the etch stop layer 306. For example, the wafer grinding operation may be performed for a duration such that the semiconductor substrate 304 is fully removed and the etch stop layer 306 remains. In some implementations, the wafer grinding operation is performed such that some material from the etch stop layer 306 is removed to ensure that the semiconductor substrate 304 is fully removed. As another example, the etch operation may be performed using an etchant that etches the semiconductor substrate 304 but removes minimal to no material from the etch stop layer 306. Thus, the etch operation may be performed until the semiconductor substrate 304 is fully removed with minimal to no etching to the etch stop layer 306.

As shown in FIG. 3E, the etch stop layer 306 is removed from the image sensor devices 100. The etch stop layer 306 may be removed after the semiconductor substrate 304 is removed. In some implementations, an etch tool is used to perform an etch operation to etch the etch stop layer 306 to remove the etch stop layer 306. The etch operation for the etch stop layer 306 may stop on the etch stop layer 308. For example, the etch operation may be performed using an etchant that etches the material of the etch stop layer 306 but removes minimal to no material from the etch stop layer 308. Thus, the etch operation may be performed until the etch stop layer 306 is fully removed with minimal to no etching to the etch stop layer 308.

As shown in FIG. 3F, the etch stop layer 308 is removed from the image sensor devices 100. The etch stop layer 308 may be removed after the etch stop layer 306 and the semiconductor substrate 304 are removed. In some implementations, an etch tool is used to perform an etch operation to etch the semiconductor substrate 304 to remove the etch stop layer 306. The etch operation for the semiconductor substrate 304 stops on the semiconductor layer 144 or on another layer (e.g., a silicon germanium (SiGe) layer, a boron-doped silicon germanium (SiGe:B) layer) on the semiconductor layer 144. For example, the etch operation may be performed using an etchant that etches the material of the etch stop layer 308 but removes minimal to no material from the semiconductor layer 144. Thus, the etch operation may be performed until the etch stop layer 308 is fully removed with minimal to no etching to the semiconductor layer 144.

As shown in FIG. 3G, a planarization operation (e.g., a CMP operation) may be performed on the semiconductor layer 144 after the etch stop layer 308 is removed. The planarization operation may be performed to planarize the top surface of the semiconductor layer 144 and to reduce the thickness of the semiconductor layer 144.

The operations described in connection with FIGS. 3A-3G to transfer or provide the semiconductor layer 144 of the sensor circuitry dies 104 onto the image sensor devices 100 include the use of low-temperature process techniques including etching and planarization. The etching and planarization techniques for removing the semiconductor substrate 304, the etch stop layer 306, and the etch stop layer 308, and the planarization techniques for reducing the thickness of the semiconductor layer 144, are preformed at sufficiently low temperatures so as to avoid affecting (or that minimally affect) the dopant profiles of the photodetector regions 114, deep cell wells 120, the shallow cell wells 122, the floating diffusion nodes 124, and/or the pickup regions 126 in the sensor layers 102 of the image sensor devices 100. Additionally and/or alternatively, the etching and planarization techniques for removing the semiconductor substrate 304, the etch stop layer 306, and the etch stop layer 308, and the planarization techniques for reducing the thickness of the semiconductor layer 144, are preformed at sufficiently low temperatures so as to not degrade (or cause minimal degradation to) silicide layers that may be formed in the sensor layers 102 of the image sensor devices 100. Additionally and/or alternatively, the etching and planarization techniques for removing the semiconductor substrate 304, the etch stop layer 306, and the etch stop layer 308, and the planarization techniques for reducing the thickness of the semiconductor layer 144, are preformed at sufficiently low temperatures so as to avoid (or with minimal likelihood of) thermal stress related damage to the layers and/or structures in the sensor layers 102 of the image sensor devices 100. These processes are performed at temperatures less than approximately 1000 degrees Celsius, and as low as 500 degrees Celsius to 700 degrees Celsius or lower.

In some implementations, the etching and planarization techniques for removing the semiconductor substrate 304, the etch stop layer 306, and the etch stop layer 308, and the planarization techniques for reducing the thickness of the semiconductor layer 144, may result in the diffusion of dopants from the etch stop layer 306 and/or the etch stop layer 308 into the semiconductor layer 144. Accordingly, the semiconductor layer 144 may include an amount of dopants that is greater at the top of the semiconductor layer 144 than at the bottom of the semiconductor layer 144 due to the etch stop layer 306 and the etch stop layer 308 being previously located on the top of the semiconductor layer 144. In some implementations, the dopant concentration of dopants from the etch stop layer 306 and/or the etch stop layer 308 in the semiconductor layer 144 ranges from approximately 3×10¹⁵ dopant atoms per cubic centimeter or greater at the top of the semiconductor layer 144 to approximately 2×10¹⁵ dopant atoms per cubic centimeter or greater at the bottom of the semiconductor layer 144. However, other values and ranges for the dopant concentration in the semiconductor layer 144 are within the scope of the present disclosure.

As shown in FIG. 3H, the semiconductor layer 144 may be etched to form the semiconductor channel layer and the source/drain regions 146 of the source-follower gate 142 (and of the other sensor control circuitry such as the row-select transistors 192 and the reset transistors 194).

In some implementations, a pattern in a photoresist layer is used to etch the semiconductor layer 144 to form the semiconductor channel layers and the source/drain regions 146. In these implementations, a deposition tool may be used to form the photoresist layer on the semiconductor layer 144. An exposure tool may be used to expose the photoresist layer to a radiation source to pattern the photoresist layer. A developer tool may be used to develop and remove portions of the photoresist layer to expose the pattern. An etch tool may be used to etch the semiconductor layer 144 based on the pattern to form the semiconductor channel layers and the source/drain regions 146. In some implementations, the etch operation includes dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the semiconductor layer 144 based on a pattern.

As shown in FIG. 3I, the active region dielectric layer 140 may be formed over and/or on the semiconductor channel layers and the source/drain regions 146. A deposition tool may be used to deposit the active region dielectric layer 140 using a PVD technique, an ALD technique, a CVD technique, an oxidation technique, and/or another suitable deposition technique. The active region dielectric layer 140 may be deposited in one or more deposition operations. In some implementations, a planarization tool may be used to perform a planarization operation (e.g., a CMP operation) to planarize the active region dielectric layer 140 after the active region dielectric layer 140 is deposited.

As shown in FIG. 3J, the gate dielectric layers 148, the gate electrodes 150, and the sidewall spacers 152 of the source-follower transistors 142 (and of the other sensor control circuitry such as the row-select transistors 192 and the reset transistors 194) may be formed. The gate dielectric layers 148, the gate electrodes 150, and the sidewall spacers 152 may be formed using similar techniques as for the transfer gates 128, as described in connection with FIGS. 2G and 2H.

As shown in FIG. 3K the CESL 154 and the dielectric layer 156 are formed over the source-follower transistors 142 (and of the other sensor control circuitry such as the row-select transistors 192 and the reset transistors 194). A deposition tool is used to deposit the CESL 154 using a conformal deposition technique such as CVD and/or ALD, among other examples. The dielectric layer 156 may then be deposited on the CESL 154 using a CVD technique, a PVD technique, an oxidation technique, and/or another suitable deposition technique. In some implementations, a planarization tool may be used to perform a planarization operation such as a CMP operation to planarize the dielectric layer 156.

As shown in FIG. 3L, recesses 310 may be formed through one or more layers of the sensor circuitry layers 104 and one or more layers of the sensor layers 102 of the image sensor devices 100. For example, a recess 310 may be formed through the gate dielectric layer 130, through the CESL 134, through the bonding dielectric layers 136 and 138, through the active region dielectric layer 140, through the CESL 154, and through the dielectric layer 156 to a pickup region 126. As another example, another recess 310 may be formed through the gate dielectric layer 130, through the CESL 134, through the bonding dielectric layers 136 and 138, through the active region dielectric layer 140, through the CESL 154, and through the dielectric layer 156 to a floating diffusion node 124. As another example, another recess 310 may be formed through the gate dielectric layer 130, through the CESL 134, through the bonding dielectric layers 136 and 138, through the active region dielectric layer 140, through the CESL 154, and through the dielectric layer 156 to a transfer gate 128.

In some implementations, a pattern in a photoresist layer is used to etch the gate dielectric layer 130, the CESL 134, the bonding dielectric layers 136 and 138, the active region dielectric layer 140, the CESL 154, and/or the dielectric layer 156 to form the recesses 310. In these implementations, a deposition tool may be used to form the photoresist layer on the dielectric layer 156. An exposure tool may be used to expose the photoresist layer to a radiation source to pattern the photoresist layer. A developer tool may be used to develop and remove portions of the photoresist layer to expose the pattern. An etch tool may be used to etch through the gate dielectric layer 130, through the CESL 134, through the bonding dielectric layers 136 and 138, through the active region dielectric layer 140, through the CESL 154, and/or through the dielectric layer 156 based on the pattern to form the recesses 310. In some implementations, the etch operation includes dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recesses 310 based on a pattern.

As shown in FIG. 3M, the recesses 310 are filled with one or more conductive materials to form contacts in the recesses 310. For example, a pickup contact 158 may be formed in a recess 310 over a pickup region 126 such that the pickup contact 158 lands on the pickup region 126. As another example, a floating diffusion contact 160 may be formed in a recess 310 over a floating diffusion node 124 such that the floating diffusion contact 160 lands on the floating diffusion node 124. As another example, a gate contact 162 may be formed in a recess 310 over a transfer gate 128 such that the gate contact 162 lands on the transfer gate 128.

A deposition tool may be used to deposit the pickup contacts 158, the floating diffusion contacts 160, and/or the gate contacts 162 using a CVD technique, a PVD technique, an ALD technique, an electroplating technique, and/or another suitable deposition technique. In some implementations, a seed layer is first deposited in a recess 310, and a pickup contact 158, a floating diffusion contact 160, or a gate contact 162 is deposited on the seed layer in the recess 310. In some implementations, a liner (e.g., a diffusion barrier, an adhesion liner) is first deposited in a recess 310, and a pickup contact 158, a floating diffusion contact 160, or a gate contact 162 is deposited on the liner in the recess 310. In some implementations, a silicide layer (e.g., a titanium silicide (TiSi) layer or another suitable metal silicide layer) is first deposited at a bottom of a recess 310, and a pickup contact 158, a floating diffusion contact 160, or a gate contact 162 is deposited on the silicide layer in the recess 310. In some implementations, a planarization tool is used to perform a planarization operation (e.g., a CMP operation) to planarize the pickup contacts 158, the floating diffusion contacts 160, and/or the gate contacts 162.

As shown in FIG. 3N, similar operations as described in connection with FIG. 3L may be performed to form recesses 312 over the gate electrodes 150 and the source/drain regions 146 of the source-follower transistors 142 (and of the other sensor control circuitry such as the row-select transistors 192 and the reset transistors 194).

As shown in FIG. 3O, similar operations as described on connection with FIG. 3M may be performed to form the source/drain contacts 164 and the gate contacts 166 of the source-follower transistors 142 (and of the other sensor control circuitry such as the row-select transistors 192 and the reset transistors 194).

As shown in FIG. 3P, the etch stop layers 168 and 174, the dielectric layers 170 and 176, the metallization layers 172, the bonding vias 178, and the bonding pads 180 may be formed. For example, the etch stop layer 168 and the dielectric layer 170 may be deposited and planarized, recesses may be formed through the etch stop layer 168 and the dielectric layer 170, and the metallization layers 172 may be formed in the recesses. As another example, the etch stop layer 174 and the bonding dielectric layer 176 may be deposited and planarized, recesses may be formed through the etch stop layer 174 and the bonding dielectric layer 176, and the bonding vias 178 and the bonding pads 180 may be formed in the recesses.

As indicated above, FIGS. 3A-3P are provided as an example. Other examples may differ from what is described with regard to FIGS. 3A-3P.

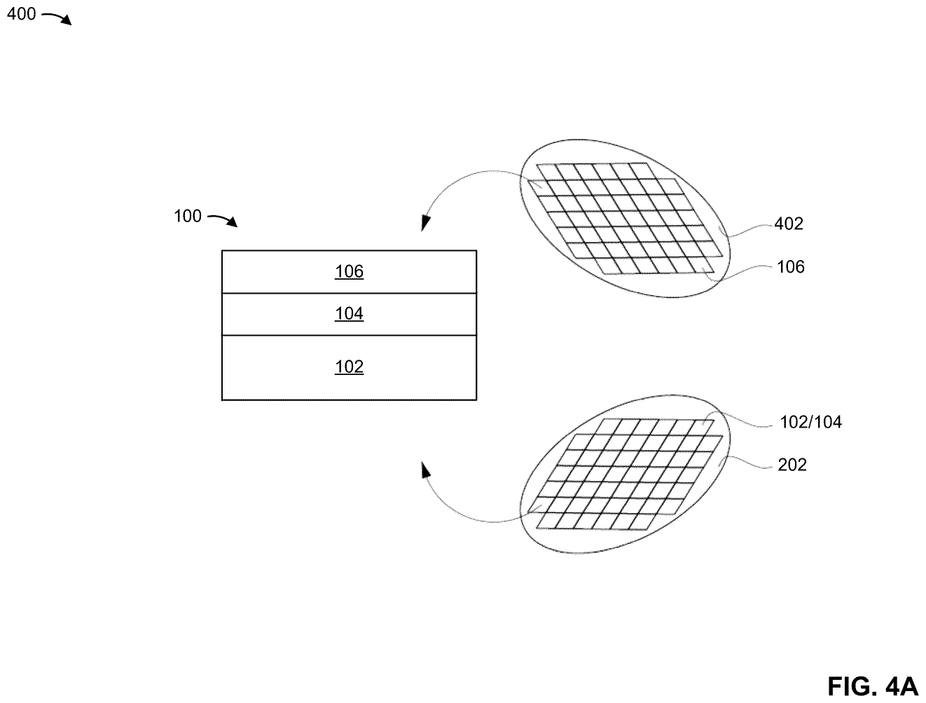

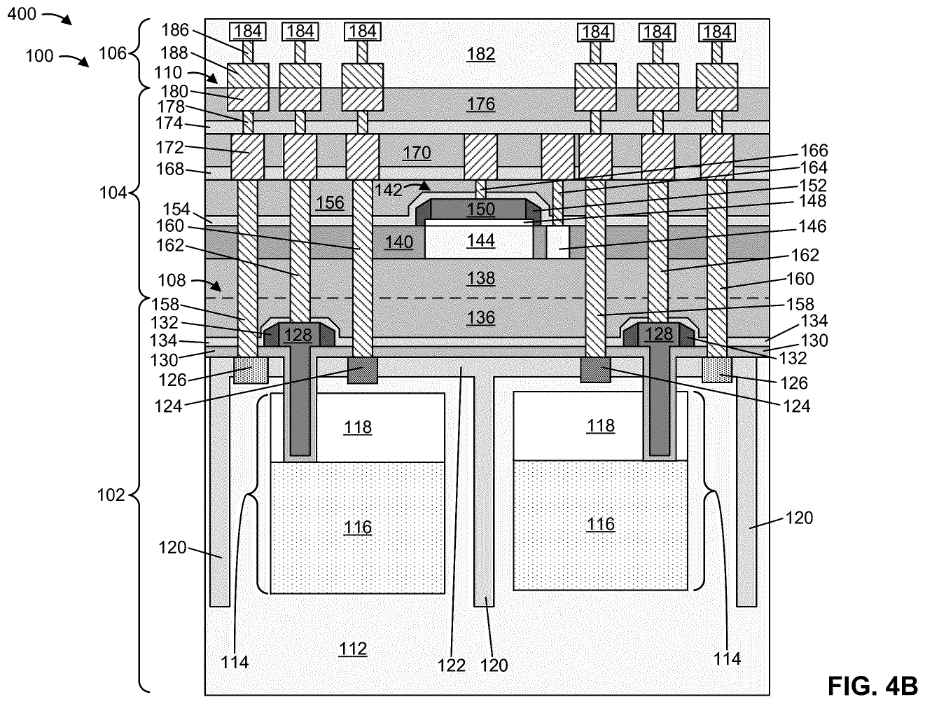

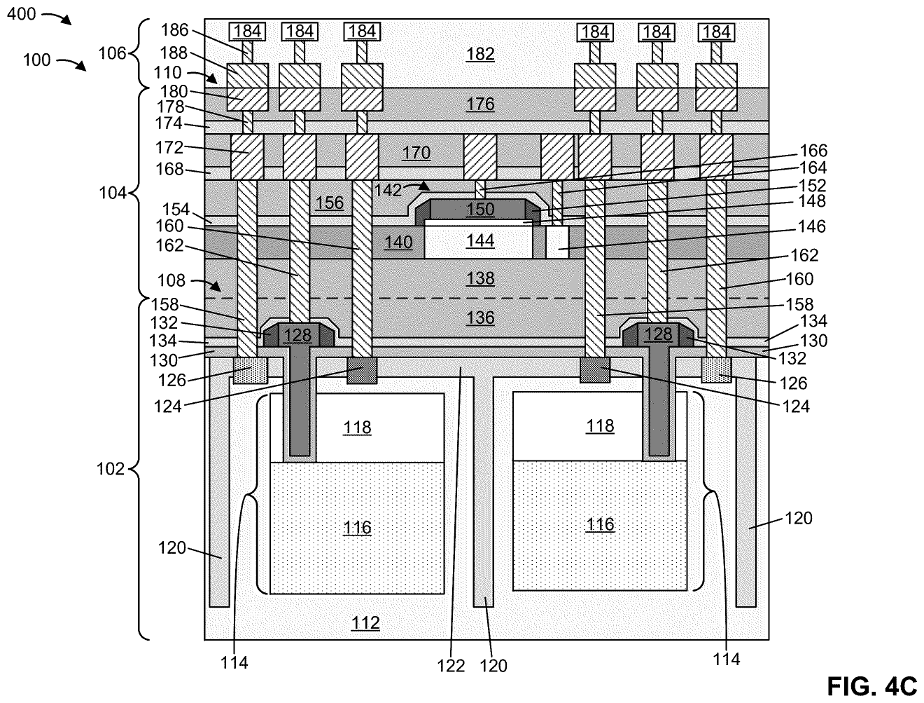

FIGS. 4A-4C are diagrams of an example 400 of bonding integrated circuit layers 106 to the image sensor devices 100 formed on a sensor wafer 202. In some implementations, one or more operations described in connection with FIGS. 4A-4C are performed using one or more semiconductor processing tools, such as a deposition tool, an exposure tool, a developer tool, an etch tool, a planarization tool, an ion implantation tool, a bonding tool, and/or a wafer/die transport tool, among other examples. In some implementations, one or more of the operations described in connection with FIGS. 4A-4C may be performed after forming the sensor layers 102 and the sensor circuitry layers 104 of the image sensor devices 100, as described in connection with FIGS. 2A-2I and 3A-3P.

As shown in FIG. 4A, an integrated circuit wafer 402 including the integrated circuit layers 106 may be bonded to the sensor wafer 202 such that the integrated circuit layers 106 of the image sensor devices 100 are bonded to the sensor circuitry layers 104 of the image sensor devices 100 on the sensor wafer 202.

As shown in FIG. 4B, a bonding tool may be used to bond an integrated circuit layer 106 to a sensor circuitry layer 104 by forming a dielectric-to-dielectric bond between the device layer 182 of the integrated circuit layer 106 and the bonding dielectric layer 176 of the sensor circuitry layer 104. Moreover, the bonding tool may be used to bond the integrated circuit layer 106 and the sensor circuitry layer 104 by forming metal-to-metal bonds between the bonding pads 188 of the integrated circuit layer 106 and the bonding pads 180 of the sensor circuitry layer 104.

As shown in FIG. 4C, a planarization operation may be performed to reduce the thickness of the back side of the semiconductor substrate 112 after the integrated circuit layers 106 of the image sensor devices 100 are bonded to the sensor circuitry layers 104 of the image sensor devices 100 on the sensor wafer 202. The planarization operation may include a CMP operation, a wafer grinding operation, and/or another suitable planarization operation.

Subsequently, the sensor wafer 202 may be diced such that the image sensor devices 100 are cut into individual dies (or individual die stacks).

As indicated above, FIGS. 4A-4C are provided as an example. Other examples may differ from what is described with regard to FIGS. 4A-4C.

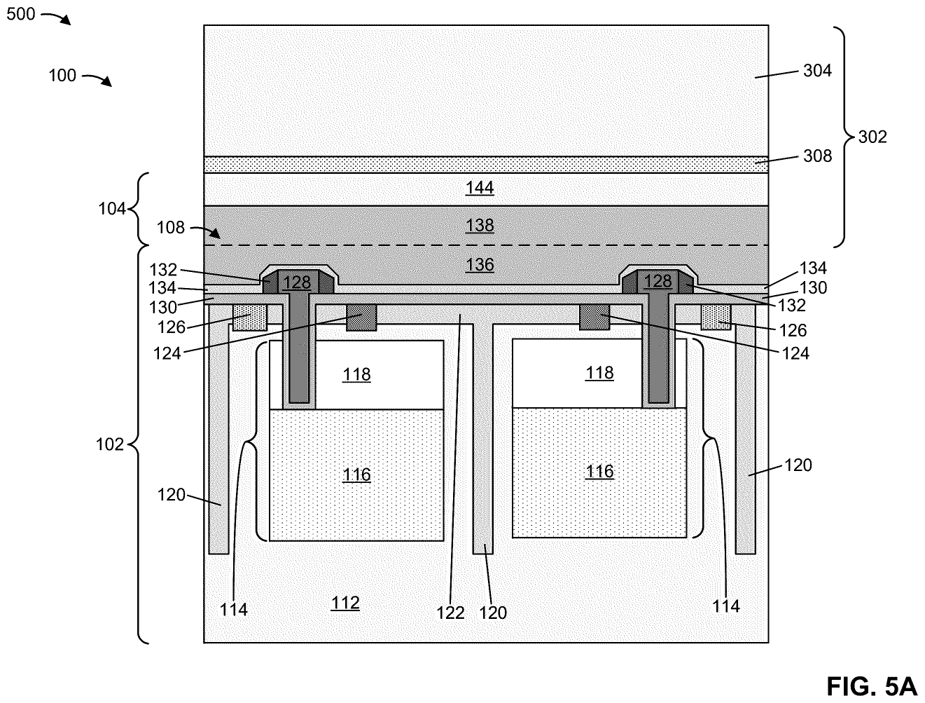

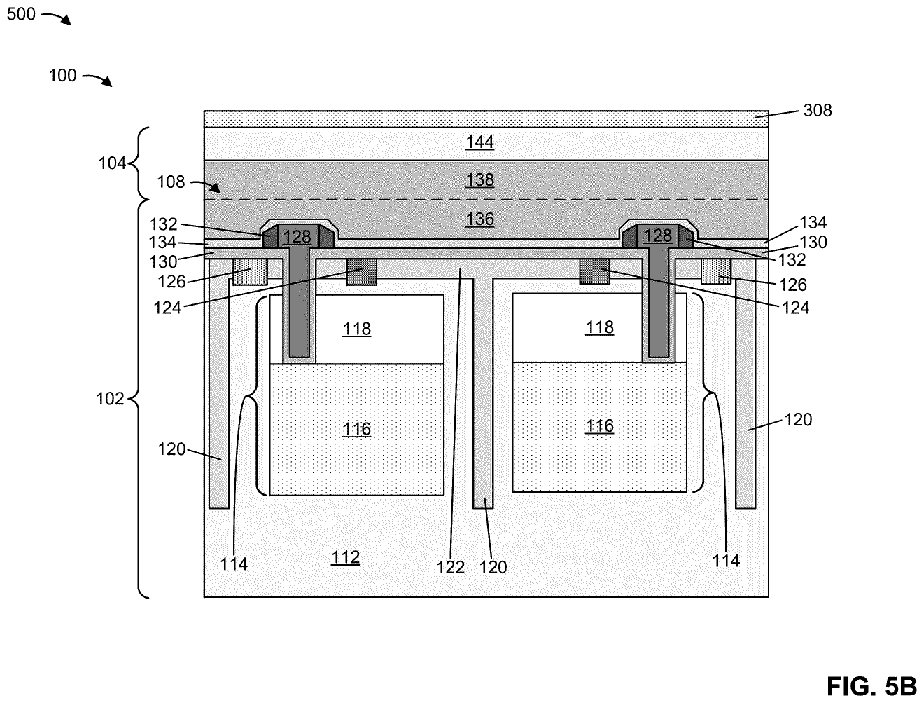

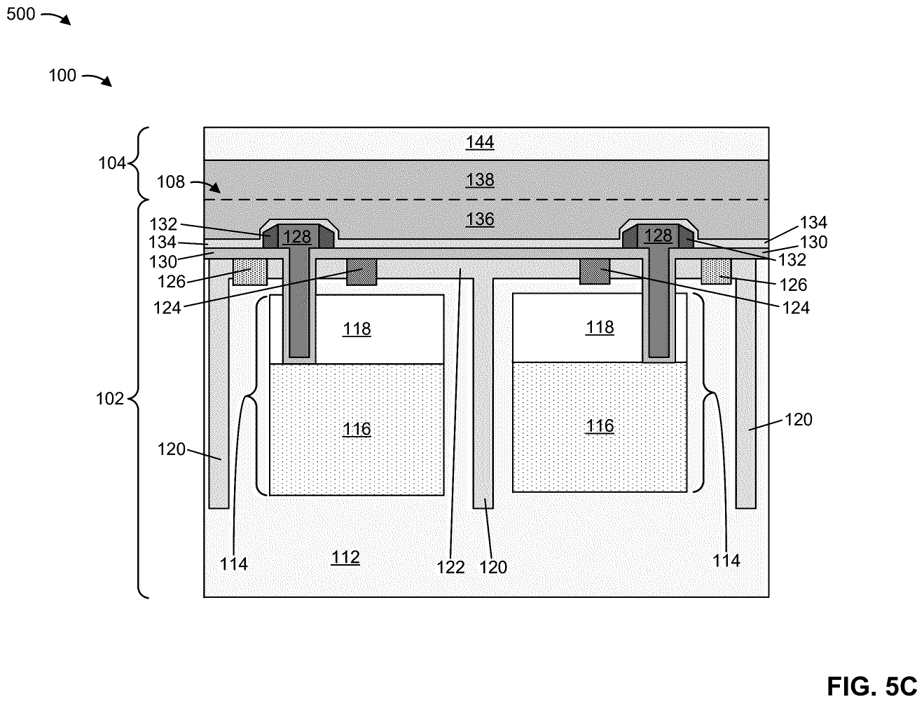

FIGS. 5A-5C are diagrams of an example 500 of forming sensor circuitry layers 104 of image sensor devices 100 formed on a sensor wafer 202. In some implementations, one or more operations described in connection with FIGS. 5A-5C are performed using one or more semiconductor processing tools, such as a deposition tool, an exposure tool, a developer tool, an etch tool, a planarization tool, an ion implantation tool, a bonding tool, and/or a wafer/die transport tool, among other examples. In some implementations, one or more of the operations described in connection with FIGS. 5A-5C may be performed after forming the sensor layers 102 of the image sensor devices 100, as described in connection with FIGS. 2A-2I.

As shown in FIG. 5A, the layer stack 302 including the semiconductor layer 144 may be bonded to the sensor wafer 202 such that the semiconductor layer 144 of the sensor circuitry layer 104 is bonded to the sensor layers 102 of the image sensor devices 100 on the sensor wafer 202. The layer stack 302 in the example 500 is similar to the layer stack 302 in the example 300, except that only one etch stop layer (e.g., the etch stop layer 308) is included in the layer stack 302.

As shown in FIGS. 5B and 5C, the semiconductor substrate 304 is removed from the image sensor devices 100 (e.g., by wafer grinding and/or etching), and the etch stop layer 308 is removed (e.g., after removal of the semiconductor substrate 304) by etching. A subsequent planarization operation may be performed on the semiconductor layer 144.

As indicated above, FIGS. 5A-5C are provided as an example. Other examples may differ from what is described with regard to FIGS. 5A-5C.

FIG. 6 is a diagram of an example 600 of elemental concentration 602 as a function of depth 604 in a semiconductor layer 144 that was provided on or bonded to a sensor circuitry layer 104 of an image sensor device 100 using low-temperature techniques described herein. As shown in FIG. 6, the elemental concentration 602 of boron (B) in the semiconductor layer 144 is greater at a top of the semiconductor layer 144 than at the bottom of the semiconductor layer 144. Moreover, a gradient 606 of boron concentration occurs in the semiconductor layer 144 because the dopant diffusion from the etch stop layer(s) 306 and/or 308 is greater at the top of the semiconductor layer 144 and gradually decreases as depth 604 increases in the semiconductor layer 144.

As indicated above, FIG. 6 is provided as an example. Other examples may differ from what is described with regard to FIG. 6.

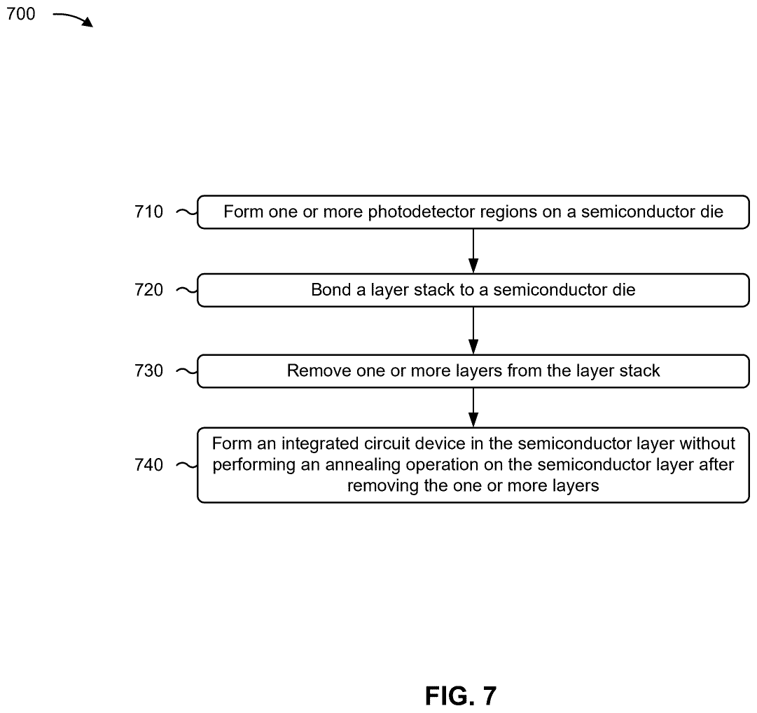

FIG. 7 is a flowchart of an example process 700 associated with forming an image sensor device described herein. In some implementations, one or more process blocks of FIG. 7 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 7, process 700 may include forming one or more photodetector regions on a semiconductor die (block 710). For example, one or more semiconductor processing tools may be used to form one or more photodetector regions (e.g., photodetector regions 114) on a semiconductor die (e.g., a sensor layer 102) of an image sensor device (e.g., an image sensor device 100), as described herein.

As further shown in FIG. 7, process 700 may include bonding a layer stack to a semiconductor die (block 720). For example, one or more semiconductor processing tools may be used to bond a layer stack (e.g., a layer stack 302) to the semiconductor die, as described herein. In some implementations, the layer stack is bonded to the semiconductor die after forming the one or more photodetector regions.

As further shown in FIG. 7, process 700 may include removing one or more layers from the layer stack (block 730). For example, one or more semiconductor processing tools may be used to remove one or more layers (e.g., a semiconductor substrate 304, an etch stop layer 306, an etch stop layer 308) from the layer stack, as described herein. In some implementations, the one or more layers may be removed from the layer stack after bonding the layer stack to the semiconductor die. In some implementations, a semiconductor layer (e.g., a semiconductor layer 144) of the layer stack remains on the semiconductor die after removal of the one or more layers.

As further shown in FIG. 7, process 700 may include forming an integrated circuit device in the semiconductor layer without performing an annealing operation on the semiconductor layer after removing the one or more layers (block 740). For example, one or more semiconductor processing tools may be used to form an integrated circuit device (e.g., a source-follower gate 142, a row-select gate 192, a reset gate 194) in the semiconductor layer without performing an annealing operation on the semiconductor layer after removing the one or more layers, as described herein.

Process 700 may include additional implementations, such as any single implementation or any combination of implementations described below and/or in connection with one or more other processes described elsewhere herein.

In a first implementation, removing the one or more layers includes performing a wafer grinding operation to remove a substrate layer (e.g., a semiconductor substrate 304) from the layer stack.

In a second implementation, alone or in combination with the first implementation, removing the one or more layers includes performing an etch operation to remove an etch stop layer (e.g., an etch stop layer 306, an etch stop layer 308) from the layer stack.

In a third implementation, alone or in combination with one or more of the first and second implementations, removing the one or more layers includes performing a first etch operation to remove a first etch stop layer (e.g., an etch stop layer 306) from the layer stack, and performing a second etch operation to remove a second etch stop layer (e.g., an etch stop layer 308) from the layer stack.

In a fourth implementation, alone or in combination with one or more of the first through third implementations, the first etch operation stops on the second etch stop layer.

In a fifth implementation, alone or in combination with one or more of the first through fourth implementations, the first etch stop layer includes a first doped semiconductor material, and the second etch stop layer includes a second doped semiconductor material that is different from the first doped semiconductor material.

In a sixth implementation, alone or in combination with one or more of the first through fifth implementations, the second doped semiconductor material includes boron-doped silicon germanium (SiGe:B).

Although FIG. 7 shows example blocks of process 700, in some implementations, process 700 includes additional blocks, fewer blocks, different blocks, or differently arranged blocks than those depicted in FIG. 7. Additionally, or alternatively, two or more of the blocks of process 700 may be performed in parallel.

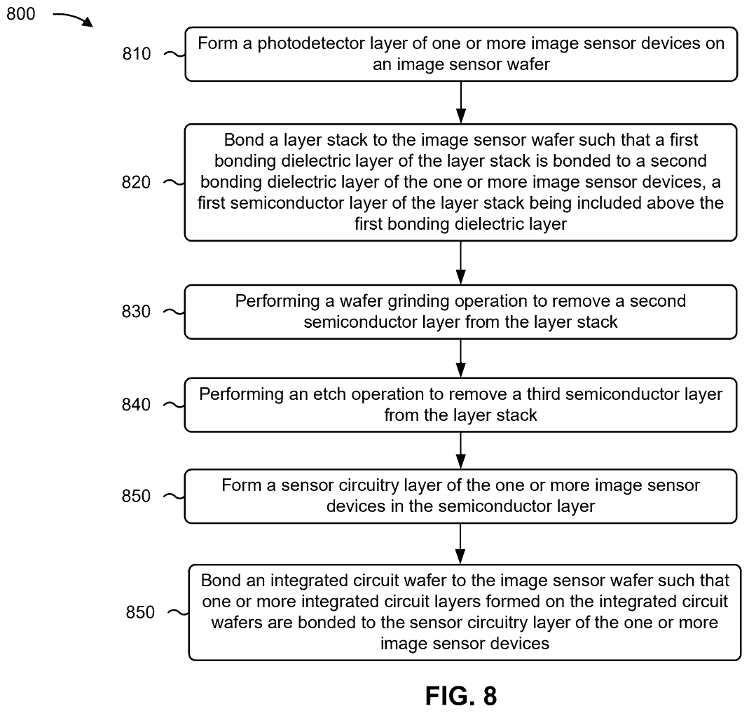

FIG. 8 is a flowchart of an example process 800 associated with forming an image sensor device described herein. In some implementations, one or more process blocks of FIG. 8 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 8, process 800 may include forming a photodetector layer of one or more image sensor devices on an image sensor wafer (block 810). For example, one or more semiconductor processing tools may be used to form a photodetector layer (e.g., a sensor layer 102) of one or more image sensor devices (e.g., one or more image sensor devices 100) on an image sensor wafer (e.g., a sensor wafer 202), as described herein.

As further shown in FIG. 8, process 800 may include bonding a layer stack to the image sensor wafer such that a first bonding dielectric layer of the layer stack is bonded to a second bonding dielectric layer of the one or more image sensor devices (block 820). For example, one or more semiconductor processing tools may be used to bond a layer stack (e.g., a layer stack 302) to the image sensor wafer such that a first bonding dielectric layer (e.g., a bonding dielectric layer 138) of the layer stack is bonded to a second bonding dielectric layer (e.g., a bonding dielectric layer 136) of the one or more image sensor devices, as described herein. In some implementations, a first semiconductor layer (e.g., a semiconductor layer 144) of the layer stack is included above the first bonding dielectric layer.

As further shown in FIG. 8, process 800 may include performing a wafer grinding operation to remove a second semiconductor layer from the layer stack (block 830). For example, one or more semiconductor processing tools may be used to perform a wafer grinding operation to remove a second semiconductor layer (e.g., a semiconductor substrate 304) from the layer stack, as described herein. In some implementations, the wafer grinding operation is performed after bonding the layer stack to the image sensor wafer.

As further shown in FIG. 8, process 800 may include performing an etch operation to remove a third semiconductor layer from the layer stack (block 830). For example, one or more semiconductor processing tools may be used to perform an etch operation to remove a third semiconductor layer (e.g., an etch stop layer 306, and etch stop layer 308), as described herein. In some implementations, the etch operation is performed after the wafer grinding operation. In some implementations, the first semiconductor layer and the first bonding dielectric layer remain on the image sensor wafer after removal of the second and third semiconductor layer. In some implementations, the second and third semiconductor layers are removed without exposing the image sensor wafer to a temperature greater than or approximately equal to 1000 degrees Celsius.

As further shown in FIG. 8, process 800 may include forming a sensor circuitry layer of the one or more image sensor devices in the semiconductor layer (block 840). For example, one or more semiconductor processing tools may be used to form a sensor circuitry layer (e.g., a sensor circuitry layer 104) of the one or more image sensor devices in the semiconductor layer, as described herein.

As further shown in FIG. 8, process 800 may include bonding an integrated circuit wafer to the image sensor wafer such that one or more integrated circuit layers formed on the integrated circuit wafers are bonded to the sensor circuitry layer of the one or more image sensor devices (block 850). For example, one or more semiconductor processing tools may be used to bond an integrated circuit wafer (e.g., an integrated circuit wafer 402) to the image sensor wafer such that one or more integrated circuit layers (e.g., one or more integrated circuit layers 106) formed on the integrated circuit wafers are bonded to the sensor circuitry layer of the one or more image sensor devices, as described herein.

Process 800 may include additional implementations, such as any single implementation or any combination of implementations described below and/or in connection with one or more other processes described elsewhere herein.

In a first implementation, the second semiconductor layer includes a semiconductor substrate (e.g., a semiconductor substrate 304), and the third semiconductor layer includes a semiconductor etch stop layer (e.g., an etch stop layer 306, an etch stop layer 308).

In a second implementation, alone or in combination with the first implementation, the wafer grinding operation stops on the semiconductor etch stop layer, and the etch operation stops on the first semiconductor layer.

In a third implementation, alone or in combination with one or more of the first and second implementations, process 800 includes performing a planarization operation on the first semiconductor layer after performing the etch operation.

In a fourth implementation, alone or in combination with one or more of the first through third implementations, process 800 includes performing another etch operation to remove a fourth semiconductor layer (e.g., an etch stop layer 306, an etch stop layer 308) from the layer stack after performing the wafer grinding operation.

In a fifth implementation, alone or in combination with one or more of the first through fourth implementations, the third semiconductor layer includes a boron-doped semiconductor material, and boron (B) from the third semiconductor layer diffuses into the first semiconductor layer after the first semiconductor layer is transferred to the image sensor wafer.

In a sixth implementation, alone or in combination with one or more of the first through fifth implementations, the third semiconductor layer includes a p-type dopant, and a concentration of the p-type dopant in the first semiconductor layer after the first semiconductor layer is transferred to the image sensor wafer is greater than a concentration of the p-type dopant in the first semiconductor layer prior to the first semiconductor layer being transferred to the image sensor wafer.

Although FIG. 8 shows example blocks of process 800, in some implementations, process 800 includes additional blocks, fewer blocks, different blocks, or differently arranged blocks than those depicted in FIG. 8. Additionally, or alternatively, two or more of the blocks of process 800 may be performed in parallel.

In this way, an image sensor device (e.g., a DoP image sensor device) is formed by forming a stacked arrangement of semiconductor dies without the use of a high-temperature operations such as annealing when processing the semiconductor wafer that contains the semiconductor layer in which the sensor circuitry die of the image sensor device is to be formed. Instead, the semiconductor wafer includes one or more etch stop layers that enable a combination of low-temperature processes such as etching and planarization to be performed to thin down semiconductor wafer. The use of low-temperature processes instead of high-temperature processes to thin down the semiconductor wafer reduces the exposure of the photodiode(s) and other layers and/or structures of the sensor wafer (e.g., silicide contacts and/or doped regions) to high temperatures that might otherwise damage these photodiode(s) and other layers and/or structures. Thus, the techniques described herein may enable a low dark current to be achieved for the photodiode(s) and/or may enable a high QE to be achieved for the photodiodes, among other examples.

As described in greater detail above, some implementations described herein provide a method. The method includes forming one or more photodetector regions on a semiconductor die. The method includes bonding a layer stack to a semiconductor die after forming the one or more photodetector regions. The method includes removing one or more layers from the layer stack after bonding the layer stack to the semiconductor die, where a semiconductor layer of the layer stack remains on the semiconductor die after removal of the one or more layers. The method includes forming an integrated circuit device in the semiconductor layer without performing an annealing operation on the semiconductor layer after removing the one or more layers.

As described in greater detail above, some implementations described herein provide a method. The method includes forming a photodetector layer of one or more image sensor devices on an image sensor wafer. The method includes bonding a layer stack to the image sensor wafer such that a first bonding dielectric layer of the layer stack is bonded to a second bonding dielectric layer of the one or more image sensor devices, where a semiconductor layer of the layer stack is included above the first bonding dielectric layer. The method includes removing one or more semiconductor layers from the layer stack after bonding the layer stack to the image sensor wafer, where the semiconductor layer and the first bonding dielectric layer remain on the image sensor wafer after removal of the one or more semiconductor layers, and where the one or more semiconductor layers are removed without exposing the image sensor wafer to a temperature greater than or approximately equal to 1000 degrees Celsius. The method includes forming a sensor circuitry layer of the one or more image sensor devices in the semiconductor layer. The method includes bonding an integrated circuit wafer to the image sensor wafer such that one or more integrated circuit layers formed on the integrated circuit wafers are bonded to the sensor circuitry layer of the one or more image sensor devices.

As described in greater detail above, some implementations described herein provide an image sensor device. The image sensor device includes a photodetector layer. The photodetector layer includes one or more photodiodes and one or more transfer gates associated with the one or more photodiodes. The image sensor device includes a sensor circuitry layer, above the photodetector layer. The sensor circuitry layer includes a source-follower transistor associated with the photodiodes, where a semiconductor channel layer of the source-follower transistor includes a semiconductor material having a p-type dopant concentration that is greater at a top of the semiconductor channel layer adjacent to a gate dielectric layer of the source-follower transistor than at a bottom of the semiconductor channel layer.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming one or more photodetector regions on a semiconductor die;
bonding a layer stack to the semiconductor die;
removing one or more layers from the layer stack,
wherein a semiconductor layer of the layer stack remains on the semiconductor die after removal of the one or more layers; and
forming an integrated circuit device in the semiconductor layer without performing an annealing operation on the semiconductor layer after removing the one or more layers.

2. The method of claim 1, wherein removing the one or more layers comprises:
performing a wafer grinding operation to remove a substrate layer from the layer stack after bonding the layer stack to the semiconductor die.

3. The method of claim 1, wherein removing the one or more layers comprises:
performing an etch operation to remove an etch stop layer from the layer stack.

4. The method of claim 1, wherein removing the one or more layers comprises:
performing a first etch operation to remove a first etch stop layer from the layer stack; and
performing a second etch operation to remove a second etch stop layer from the layer stack.

5. The method of claim 4, wherein the first etch operation stops on the second etch stop layer.

6. The method of claim 4, wherein the first etch stop layer comprises a first doped semiconductor material; and
wherein the second etch stop layer comprises a second doped semiconductor material that is different from the first doped semiconductor material.

7. The method of claim 6, wherein the second doped semiconductor material comprises boron-doped silicon germanium (SiGe:B).

8. A method, comprising:
forming a photodetector layer of one or more image sensor devices on an image sensor wafer;
bonding a layer stack to the image sensor wafer such that a first bonding dielectric layer of the layer stack is bonded to a second bonding dielectric layer of the one or more image sensor devices,
wherein a first semiconductor layer of the layer stack is included above the first bonding dielectric layer;
performing a wafer grinding operation to remove a second semiconductor layer from the layer stack;
performing an etch operation to remove a third semiconductor layer from the layer stack,
wherein the first semiconductor layer and the first bonding dielectric layer remain on the image sensor wafer after removal of the one or more semiconductor layers;
forming a sensor circuitry layer of the one or more image sensor devices in the semiconductor layer; and
bonding an integrated circuit wafer to the image sensor wafer such that one or more integrated circuit layers formed on the integrated circuit wafers are bonded to the sensor circuitry layer of the one or more image sensor devices.

9. The method of claim 8, wherein the second semiconductor layer comprises a semiconductor substrate;
wherein the third semiconductor layer comprises a semiconductor etch stop layer; and
wherein performing the etch operation to remove the third semiconductor layer from the layer stack comprises:
performing the etch operation, after performing the wafer grinding operation, to remove the third semiconductor layer from the layer stack.

10. The method of claim 8, wherein the wafer grinding operation stops on the third semiconductor layer; and
wherein the etch operation stops on the first semiconductor layer.

11. The method of claim 8, further comprising:
performing a planarization operation on the first semiconductor layer after performing the etch operation.

12. The method of claim 8, further comprising:
performing another etch operation to remove a fourth semiconductor layer from the layer stack after performing the wafer grinding operation.

13. The method of claim 8, wherein the third semiconductor layer comprises a boron-doped semiconductor material; and
wherein boron (B) from the third semiconductor layer diffuses into the first semiconductor layer after the first semiconductor layer is transferred to the image sensor wafer.

14. The method of claim 8, wherein the third semiconductor layer comprises a p-type dopant; and
wherein a concentration of the p-type dopant in the first semiconductor layer after the first semiconductor layer is transferred to the image sensor wafer is greater than a concentration of the p-type dopant in the first semiconductor layer prior to the first semiconductor layer being transferred to the image sensor wafer.

15. An image sensor device, comprising:
a photodetector layer comprising:
one or more photodiodes; and
one or more transfer gates associated with the one or more photodiodes; and
a sensor circuitry layer, above the photodetector layer, comprising a source-follower gate associated with the photodiodes,
wherein a semiconductor channel layer of the source-follower gate comprises a semiconductor material having a dopant concentration that is greater at a top of the semiconductor channel layer adjacent to a gate dielectric layer of the source-follower gate than at a bottom of the semiconductor channel layer.

16. The image sensor device of claim 15, wherein the dopant concentration at the top of the semiconductor channel layer is greater than approximately 3×10¹⁵ atoms per cubic centimeter.

17. The image sensor device of claim 15, wherein the dopant concentration decreases from the top of the semiconductor channel layer to the bottom of the semiconductor channel layer.

18. The image sensor device of claim 15, wherein the semiconductor channel layer comprises a boron (B) dopant.

19. The image sensor device of claim 15, further comprising:
an integrated circuit layer, above the sensor circuitry layer, comprising one or more integrated circuit devices.

20. The image sensor device of claim 15, wherein the sensor circuitry layer further comprises at least one of:
a row-select transistor associated with the one or more photodiodes, or
a reset transistor associated with the one or more photodiodes,
wherein at least one of the row-select transistor or the reset transistor comprises another semiconductor channel layer that includes a semiconductor material having a dopant concentration that is greater at a top of the other semiconductor channel layer than at a bottom of the other semiconductor channel layer.
